(19) United States
(12) Patent Application Publication
(10) Pub. No.: US 2026/0255992 A1
(43) Pub. Date: Aug. 27, 2026

(54) WIRING STRUCTURE AND METHOD FOR MANUFACTURING THE SAME

(71) Applicant: Advanced Semiconductor Engineering, Inc., Kaohsiung (TW)

(72) Inventor: Wen Hung HUANG, Kaohsiung (TW)

(73) Assignee: Advanced Semiconductor Engineering, Inc., Kaohsiung (TW)

(21) Appl. No.: 19/651,454

(22) Filed: Apr. 17, 2026

Related U.S. Application Data
(63) Continuation of application No. 17/092,196, filed on Nov. 6, 2020.

(51) Int. Cl. H10W 70/60; H10W 70/05; H10W 70/63; H10W 70/685; H10W 90/00

(52) U.S. Cl. CPC H10W 70/611; H10W 70/05; H10W 70/635; H10W 70/685; H10W 90/401

(57) ABSTRACT

A wiring structure and a method for manufacturing the same are provided. The wiring structure includes a conductive structure, an intermediate structure and a seed layer. The conductive structure includes at least one dielectric layer and at least one circuit layer in contact with the dielectric layer. The conductive structure defines an accommodating hole. The intermediate structure is bonded to an inner surface of the accommodating hole. The seed layer is bonded to the accommodating hole through the intermediate structure.

### CROSS REFERENCE TO RELATED APPLICATION

This application is a continuation of U.S. patent application Ser. No. 17/092,196, filed Nov. 6, 2020, the content of which is incorporated herein by reference in its entirety.

### BACKGROUND

### 1. Field of the Disclosure

The present disclosure relates to a wiring structure and a manufacturing method, and to a wiring structure including at least two seed layers, and a method for manufacturing the same.

### 2. Description of the Related Art

Along with the rapid development in electronics industry and the progress of semiconductor processing technologies, semiconductor chips are integrated with an increasing number of electronic components to achieve improved electrical performance and additional functions. Accordingly, the semiconductor chips are provided with more input/output (I/O) connections. To manufacture semiconductor packages including semiconductor chips with an increased number of I/O connections, circuit layers of semiconductor substrates used for carrying the semiconductor chips may correspondingly increase in size. Thus, a thickness and a warpage of the semiconductor substrate may correspondingly increase, and a yield of the semiconductor substrate may decrease.

### SUMMARY

In some embodiments, a wiring structure includes a conductive structure, an intermediate structure and a seed layer. The conductive structure includes at least one dielectric layer and at least one circuit layer in contact with the dielectric layer. The conductive structure defines an accommodating hole. The intermediate structure is bonded to an inner surface of the accommodating hole. The seed layer is bonded to the accommodating hole through the intermediate structure.

In some embodiments, a method for manufacturing a wiring structure includes: (a) providing a conductive structure including at least one dielectric layer and at least one circuit layer in contact with the dielectric layer, wherein the conductive structure defines an accommodating hole; (b) bonding an intermediate structure to an inner surface of the accommodating hole; and (c) bonding a seed layer to the accommodating hole through the intermediate structure.

### BRIEF DESCRIPTION OF THE DRAWINGS

Aspects of some embodiments of the present disclosure are best understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of a wiring structure according to some embodiments of the present disclosure.

FIG. 2 illustrates a partially enlarged view of a region “A” in FIG. 1.

FIG. 3 illustrates a cross-sectional view of a wiring structure according to some embodiments of the present disclosure.

FIG. 4 illustrates a partially enlarged view of a region “C” in FIG. 3.

FIG. 5 illustrates a cross-sectional view of a wiring structure according to some embodiments of the present disclosure.

FIG. 6 illustrates a cross-sectional view of a wiring structure according to some embodiments of the present disclosure.

FIG. 7 illustrates a cross-sectional view of a bonding of a package structure and a substrate according to some embodiments of the present disclosure.

FIG. 8 illustrates one or more stages of an example of a method for manufacturing a wiring structure according to some embodiments of the present disclosure.

FIG. 9 illustrates one or more stages of an example of a method for manufacturing a wiring structure according to some embodiments of the present disclosure.

FIG. 10 illustrates one or more stages of an example of a method for manufacturing a wiring structure according to some embodiments of the present disclosure.

FIG. 11 illustrates one or more stages of an example of a method for manufacturing a wiring structure according to some embodiments of the present disclosure.

FIG. 12 illustrates one or more stages of an example of a method for manufacturing a wiring structure according to some embodiments of the present disclosure.

FIG. 13 illustrates one or more stages of an example of a method for manufacturing a wiring structure according to some embodiments of the present disclosure.

FIG. 14 illustrates one or more stages of an example of a method for manufacturing a wiring structure according to some embodiments of the present disclosure.

FIG. 15 illustrates one or more stages of an example of a method for manufacturing a wiring structure according to some embodiments of the present disclosure.

FIG. 16 illustrates one or more stages of an example of a method for manufacturing a wiring structure according to some embodiments of the present disclosure.

FIG. 17 illustrates one or more stages of an example of a method for manufacturing a wiring structure according to some embodiments of the present disclosure.

FIG. 18 illustrates one or more stages of an example of a method for manufacturing a wiring structure according to some embodiments of the present disclosure.

FIG. 19 illustrates one or more stages of an example of a method for manufacturing a wiring structure according to some embodiments of the present disclosure.

FIG. 20 illustrates one or more stages of an example of a method for manufacturing a wiring structure according to some embodiments of the present disclosure.

FIG. 21 illustrates one or more stages of an example of a method for manufacturing a wiring structure according to some embodiments of the present disclosure.

FIG. 22 illustrates one or more stages of an example of a method for manufacturing a wiring structure according to some embodiments of the present disclosure.

FIG. 23 illustrates one or more stages of an example of a method for manufacturing a wiring structure according to some embodiments of the present disclosure.

FIG. 24 illustrates one or more stages of an example of a method for manufacturing a wiring structure according to some embodiments of the present disclosure.

FIG. 25 illustrates one or more stages of an example of a method for manufacturing a wiring structure according to some embodiments of the present disclosure.

FIG. 26 illustrates one or more stages of an example of a method for manufacturing a wiring structure according to some embodiments of the present disclosure.

FIG. 27 illustrates one or more stages of an example of a method for manufacturing a wiring structure according to some embodiments of the present disclosure.

FIG. 28 illustrates one or more stages of an example of a method for manufacturing a wiring structure according to some embodiments of the present disclosure.

FIG. 29 illustrates one or more stages of an example of a method for manufacturing wiring structure according to some embodiments of the present disclosure.

FIG. 30 illustrates one or more stages of an example of a method for manufacturing a wiring structure according to some embodiments of the present disclosure.

FIG. 31 illustrates one or more stages of an example of a method for manufacturing a wiring structure according to some embodiments of the present disclosure.

FIG. 32 illustrates one or more stages of an example of a method for manufacturing a wiring structure according to some embodiments of the present disclosure.

FIG. 33 illustrates one or more stages of an example of a method for manufacturing a wiring structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

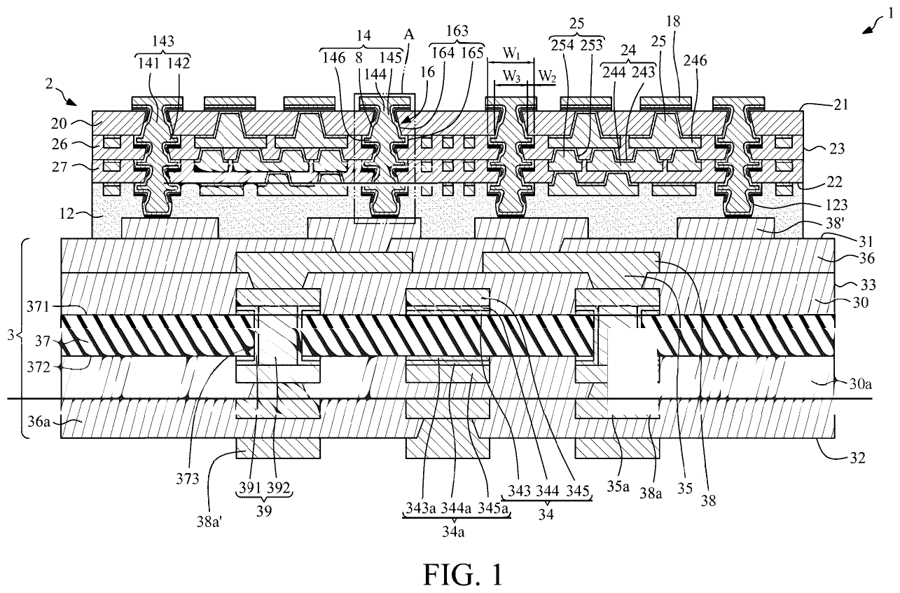

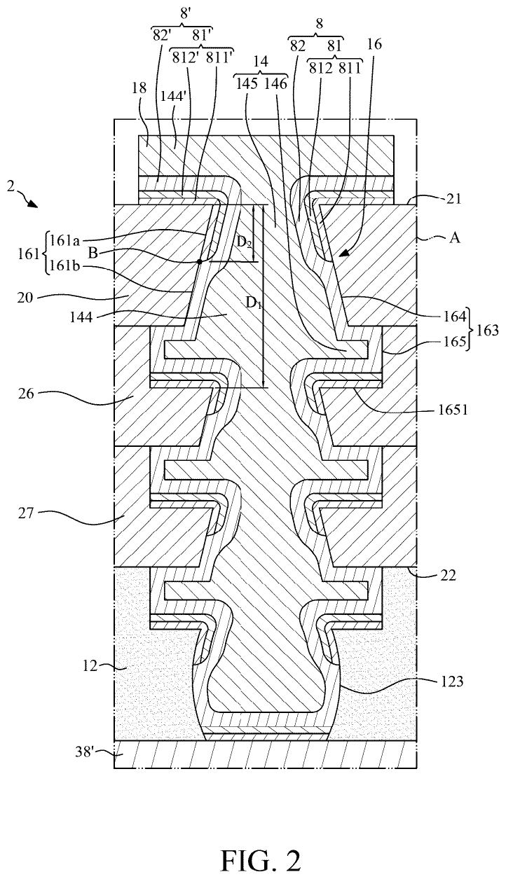

FIG. 1 illustrates a cross-sectional view of a wiring structure 1 according to some embodiments of the present disclosure. FIG. 2 illustrates a partially enlarged view of a region “A” in FIG. 1. The wiring structure 1 may include a lower conductive structure 3, an upper conductive structure 2, a bonding layer 12, at least one conductive through via 14 and an outer circuit layer 18.

The upper conductive structure 2 (also referred to as “a conductive structure”) is disposed on the lower conductive structure 3, and includes a plurality of dielectric layers (including, for example, a first dielectric layer 20, a second dielectric layer 26 and a third dielectric layer 27), a plurality of circuit layers 24 (formed of a metal, a metal alloy, or other conductive material) in contact with the dielectric layers 20, 26, 27, and a plurality of inner conductive vias 25. In some embodiments, the upper conductive structure 2 may be similar to a coreless substrate, and may be a bumping level redistribution structure. The upper conductive structure 2 may be also referred to as “a high-density conductive structure” or “a high-density stacked structure”. The circuit layers 24 of the upper conductive structure 2 may be also referred to as “a high-density circuit layer”. In some embodiments, a density of a circuit line (including, for example, a trace or a pad) of the high-density circuit layer is greater than a density of a circuit line of a low-density circuit layer. That is, the count of the circuit line (including, for example, the trace or the pad) in a unit area of the high-density circuit layer is greater than the count of the circuit line iam equal unit area of the low-density circuit layer, such as about 1.2 times or greater, about 1.5 times or greater, or about 2 times or greater, or about 3 times or greater. Alternatively, or in combination, a line width/line space (L/S) of the high-density circuit layer is less than an L/S of the low-density circuit layer, such as about 90% or less, about 50% or less, or about 20% or less. Further, the conductive structure that includes the high-density circuit layer may be designated as the “high-density conductive structure”, and the conductive structure that includes the low-density circuit layer may be designated as a “low-density conductive structure”.

The upper conductive structure 2 has a top surface 21, a bottom surface 22 opposite to the top surface 21, and a lateral surface 23 extending between the top surface 21 and the bottom surface 22. As shown in FIG. 1, the dielectric layers 20, 26, 27 are stacked on one another. For example, the first dielectric layer 20 may be the topmost dielectric layer. In some embodiments, a material of the dielectric layers 20, 26, 27 is transparent, and can be seen through or detected by human eyes or machine. In some embodiments, a transparent material of the dielectric layers 20, 26, 27 has a light transmission for a wavelength in the visible range (or other pertinent wavelength for detection of a mark) of at least about 60%, at least about 70%, or at least about 80%. In some embodiments, a material of the dielectric layers 20, 26, 27 may be made of a cured photoimageable dielectric (PID) material such as epoxy or polyimide (PI) including photoinitiators.

The circuit layers 24 may be fan-out circuit layers or redistribution layers (RDLs), and an L/S of the circuit layers 24 may be less than about 10 μm/10 μm., less than or equal to 8 μm/8 μm, less than or equal to 5 μm/5 μm, less than or equal to 3 μm/ 3μm, less than or equal to about 2 μm/about 2 μm, or less than or equal to about 1.8 μm/about 1.8μm. In some embodiments, the circuit layer 24 is embedded in the corresponding dielectric layers 20, 26, 27. In some embodiments, each circuit layer 24 may include a seed layer 243 and a conductive material 244 (e.g., a plating metallic material) disposed on the seed layer 243. As illustrated in the embodiment of FIG. 1, a horizontally connecting or extending circuit layer may be omitted in the first dielectric layer 20.

Some of the inner conductive vias 25 are disposed between two adjacent circuit layers 24 for electrically connecting the two circuit layers 24. Some of the inner conductive vias 25 are exposed from the top surface 21 of the upper conductive structure 2 (e.g., the top surface of the first dielectric layer 20). In some embodiments, each inner conductive via 25 may include a seed layer 253 and a conductive material 254 (e.g., a plating metallic material) disposed on the seed layer 253. Each inner conductive via 25 tapers upwardly along a direction from the bottom surface 22 towards the top surface 21 of the upper conductive structure 2.

As shown in FIG. 1 and FIG. 2, the dielectric layers 20, 26, 27 of the upper conductive structure 2 together define an accommodating hole 16 extending through the dielectric layers 20, 26, 27 for accommodating the conductive through via 14.

The lower conductive structure 3 includes at least one dielectric layer (including, for example, one first upper dielectric layer 30, one second upper dielectric layer 36, one first lower dielectric layer 30a and one second lower dielectric layer 36a), at least one circuit layer (including, for example, one first upper circuit layer 34, two second upper circuit layers 38, 38′, one first lower circuit layer 34a and two second lower circuit layers 38a, 38a′ formed of a metal, a metal alloy, or other conductive material) in contact with the dielectric layer(s) 30, 36, 30a, 36a, and at least one inner conductive via (including, for example, a plurality of upper interconnection vias 35 and a plurality of lower interconnection vias 35a). In some embodiments, the lower conductive structure 3 may be similar to a core substrate that further includes a core portion 37. The lower conductive structure 3 may be also referred to as “a lower stacked structure” or “a low-density conductive structure” or “a low-density stacked structure”. The circuit layers 34, 38, 38′, 34a, 38a, 38a′ of the lower conductive structure 3 may be also referred to as “a low-density circuit layer”. As shown in FIG. 1, the lower conductive structure 3 has a top surface 31, a bottom surface 32 opposite to the top surface 31, and a lateral surface 33 extending between the top surface 31 and the bottom surface 32. As shown in FIG. 1, the lateral surface 23 of the upper conductive structure 2 may be displaced or recessed from the lateral surface 33 of the lower conductive structure 3.

The core portion 37 has a top surface 371 and a bottom surface 372 opposite the top surface 371, and defines a plurality of through holes 373 extending through the core portion 37. An interconnection via 39 is disposed or formed in each through hole 373 for vertical connection. In some embodiments, the interconnection via 39 includes a base metallic layer 391 and an insulation material 392. The base metallic layer 391 is disposed or formed on a side wall of the through hole 373, and defines a central through hole. The insulation material 392 fills the central through hole defined by the base metallic layer 391. In some embodiments, the interconnection via 39 may omit the insulation material 392, and may include a bulk metallic material that fills the first through hole 373.

The first upper dielectric layer 30 is disposed on the top surface 371 of the core portion 37. The second upper dielectric layer 36 is stacked or disposed on the first upper dielectric layer 30. In addition, the first lower dielectric layer 30a is disposed on the bottom surface 372 of the core portion 37. The second lower dielectric layer 36a is stacked or disposed on the first lower dielectric layer 30a.

A thickness of each of the dielectric layers 20, 26, 27 of the upper conductive structure 2 is less than or equal to about 40%, less than or equal to about 35%, or less than or equal to about 30% of a thickness of each of the dielectric layers 30, 36, 30 a, 36 a of the lower conductive structure 3. For example, a thickness of each of the dielectric layers 20, 26, 27 of the upper conductive structure 2 may be less than or equal to about 7 μm, and a thickness of each of the dielectric layers 30, 36, 30a, 36a of the lower conductive structure 3 may be about 40μm. In addition, a material of the dielectric layers 30, 36, 30 a, 36 a of the lower conductive structure 3 may be different from the material of the dielectric layers 20, 26, 27 of the upper conductive structure 2. For example, the material of the dielectric layers 30, 36, 30a, 36a of the lower conductive structure 3 may be polypropylene (PP) or ajinomoto build-up film (ABF).

An L/S of the first upper circuit layer 34 may be greater than or equal to about 10 μm/about 10 μm. Thus, the L/S of the first upper circuit layer 34 may be greater than or equal to about five times the L/S of the circuit layer 24 of the upper conductive structure 2. In some embodiments, the first upper circuit layer 34 is formed or disposed on the top surface 371 of the core portion 37, and covered by the first upper dielectric layer 30. In some embodiments, the first upper circuit layer 34 may include a first metallic layer 343, a second metallic layer 344 and a third metallic layer 345. The first metallic layer 343 is disposed on the top surface 371 of the core portion 37, and may be formed from a copper foil (e.g., may constitute a portion of the copper foil). The second metallic layer 344 is disposed on the first metallic layer 343, and may be a plated copper layer. The third metallic layer 345 is disposed on the second metallic layer 344, and may be another plated copper layer. In some embodiments, the third metallic layer 345 may be omitted.

An L/S of the second upper circuit layer 38 may be substantially equal to the of the first upper circuit layer 34. In some embodiments, the second upper circuit layer 38 is formed or disposed on the first upper dielectric layer 30, and covered by the second upper dielectric layer 36. In some embodiments, the second upper circuit layer 38 is electrically connected to the first upper circuit layer 34 through the upper interconnection vias 35. Each upper interconnection via 35 tapers downwardly along a direction from the top surface 31 towards the bottom surface 32 of the lower conductive structure 3. In addition, in some embodiments, the second upper circuit layer 38′ is disposed on and protrudes from the top surface of the second upper dielectric layer 36. In some embodiments, the second upper circuit layer 38 is electrically connected to the second upper circuit layer 38′ through the upper interconnection vias 35. In some embodiments, the second upper circuit layer 38′ is the topmost circuit layer of the lower conductive structure 3.

An L/S of the first lower circuit layer 34a may be substantially equal to the L/of the first upper circuit layer 34. In some embodiments, the first lower circuit layer 34a is formed or disposed on the bottom surface 372 of the core portion 37, and covered by the first lower dielectric layer 30a. In some embodiments, the first lower circuit layer 34a may include a first metallic layer 343a, a second metallic layer 344a and a third metallic layer 345a. The first metallic layer 343a is disposed on the bottom surface 372 of the core portion 37, and may be formed from a copper foil. The second metallic layer 344a is disposed on the first metallic layer 343a, and may be a plated copper layer. The third metallic layer 345a is disposed on the second metallic layer 344a, and may be another plated copper layer. In some embodiments, the third metallic layer 345a may be omitted.

An L/S of the second lower circuit layer 38a may be substantially equal to the L/S of the first upper circuit layer 34. In some embodiments, the second lower circuit layer 38a is formed or disposed on the first lower dielectric layer 30a, and covered by the second lower dielectric layer 36a. In some embodiments, the second lower circuit layer 38a is electrically connected to the first lower circuit layer 34a through the lower interconnection vias 35a. The lower interconnection via 35a tapers upwardly along a direction from the bottom surface 32 towards the top surface 31 of the lower conductive structure 3.

In addition, in some embodiments, the second lower circuit layer 38a′ is dispos on and protrudes from the bottom surface of the second lower dielectric layer 36a. In some embodiments, the second lower circuit layer 38a′ is electrically connected to the second lower circuit layer 38a through the lower interconnection vias 35a. In some embodiments, the second lower circuit layer 38a′ is the bottommost low-density circuit layer of the lower conductive structure 3.

In some embodiments, each interconnection via 39 electrically connects the first upper circuit layer 34 and the first lower circuit layer 34a. The base metallic layer 391 of the interconnection via 39, the second metallic layer 344 of the first upper circuit layer 34 and the second metallic layer 344a the first lower circuit layer 34a may be formed integrally and concurrently as a monolithic or one-piece structure.

The bonding layer 12 is interposed or disposed between the upper conductive structure 2 and the lower conductive structure 3 to bond the upper conductive structure 2 and the lower conductive structure 3 together. That is, the bonding layer 12 adheres to the bottom surface 22 of the upper conductive structure 2 and the top surface 31 of the lower conductive structure 3. In some embodiments, the bonding layer 12 may be an adhesion layer that is cured from a single adhesive material (e.g., includes a cured adhesive material such as an adhesive polymeric material). Thus, the bottommost circuit layer 24 of the upper conductive structure 2 and the topmost circuit layer (e.g., the second upper circuit layer 38′) of the lower conductive structure 3 are embedded in the bonding layer 12.

In some embodiments, a material of the bonding layer 12 is transparent, and can be seen through by human eyes or machine. That is, a mark disposed adjacent to the top surface 31 of the lower conductive structure 3 can be recognized or detected from the top surface 21 of the upper conductive structure 2 by human eyes or machine. In addition, the material of the bonding layer 12 may be different from the material of the dielectric layers 30, 36, 30a, 36a of the lower conductive structure 3 and the material of the dielectric layers 20, 26, 27 of the upper conductive structure 2. For example, the material of the bonding layer 12 may be ABF, or ABF-like dielectric film. Furthermore, the bonding layer 12 may define at least one through hole 123 extending through the bonding layer 12, and terminating at or on a topmost circuit layer (e.g., the second upper circuit layer 38′) of the lower conductive structure 3. In some embodiments, the sidewall of the through hole 123 of the bonding layer 12 may be curved since it may be formed by plasma. The through hole 123 of the bonding layer 12 may expose a portion of the topmost circuit layer (e.g., a top surface of the second upper circuit layer 38′) of the lower conductive structure 3.

As shown in FIG. 1 and FIG. 2, the through hole 123 of the bonding layer 12 may be aligned with and in communication with the accommodating hole 16 of the upper conductive structure 2 for accommodating the conductive through via 14. In some embodiments, the through hole 123 of the bonding layer 12 may be a portion of the accommodating hole 16. Thus, the accommodating hole 16 extends through the upper conductive structure 2 and the bonding layer 12, and exposes a portion of a circuit layer (e.g., the second upper circuit layer 38′) of the lower conductive structure 3. Further, the accommodating hole 16 includes a plurality of unit portions 163 corresponding to a respective one of the dielectric layers 20, 26, 27. Each of the unit portions 163 includes a first portion 164 and a second portion 165. The first portions 164 of the unit portions 163 taper upward. The second portion 165 is disposed on a bottom portion of the first portion 164 and extends horizontally. For example, each of the unit portions 163 may be substantially in an inverted “T” shape.

The conductive through via 14 may be disposed in the accommodating hole 16 and the through hole 123 of the bonding layer 12 to electrically connect the upper conductive structure 2 and the lower conductive structure 3. Thus, a bottom portion of the conductive through via 14 may be disposed in the through hole 123 of the bonding layer 12. The conductive through via 14 may further extend through the through hole 123 of the bonding layer 12, and is electrically connected to the topmost circuit layer (e.g., the top surface of the second upper circuit layer 38′) of the lower conductive structure 3. The conductive through via 14 extends from the top surface 21 of the upper conductive structure 2 to the bottom surface of the bonding layer 12 to terminate at or on a portion of the topmost circuit layer (e.g., the top surface of the second upper circuit layer 38′) of the lower conductive structure 3. Thus, the conductive through via 14 extends through the upper conductive structure 2, and a length of the conductive through via 14 is greater than a thickness of the upper conductive structure 2. In some embodiments, the upper conductive structure 2 is electrically connected to the lower conductive structure 3 only through the conductive through via 14.

The conductive through via 14 may be a monolithic or one-piece structure. A lateral side surface (i.e., a boundary between the conductive through via 14 and the dielectric layers 20, 26, 27) of the conductive through via 14 is not a continuous or smooth surface. The conductive through via 14 may include a seed layer 8, a main portion 145 and at least one extending portion 146. In some embodiments, the conductive through via 14 includes a plurality of extending portions 146 protruding from the main portion 145. The main portion 145 and the extending portions 146 may be formed integrally and concurrently. In addition, the main portion 145 and the extending portions 146 may include a conductive material (or conductive channel) 144 (e.g., a plating metallic material such as copper) disposed on the seed layer 8. The seed layer 8 may be interposed between the main portion 145 and the dielectric layers 20, 26, 27, and between the extending portions 146 and the dielectric layers 20, 26. Thus, the main portion 145 and the extending portions 146 (e.g., the conductive material 144) may not contact the dielectric layers 20, 26, 27. As shown in FIG. 1, the conductive material 144 may be disposed on the second seed layer 82 and may fill the accommodating hole 16 to form the conductive through via 14.

In some embodiments, the conductive material 144 of the conductive through vi 14 may be different from the conductive material 244 of the circuit layer 24. For example, the conductive material 144 of the conductive through via 14 may include copper-iron composite, and the conductive material 244 of the circuit layer 24 may include copper sulfate. In addition, a lattice of the conductive material 144 of the conductive through via 14 may be different form a lattice of the conductive material 244 of the circuit layer 24. A grain size of the conductive material 144 of the conductive through via 14 may be greater than a grain size of the conductive material 244 of the circuit layer 24.

As shown in FIG. 2, the seed layer 8 may include a first seed layer 81 and a second seed layer 82. The first seed layer 81 is discontinuous. A portion of the first seed layer 81 is disposed on the top surface 21 of the upper conductive structure 2, and further extends to be disposed on a first portion 161a of an inner surface 161 of the accommodating hole 16. Another portion of the first seed layer 81 covers and contacts a bottom surface 1651 of the second portion 165 of the accommodating hole 16. Thus, a portion (e.g., a second portion 161b) of the inner surface 161 of the accommodating hole 16 is not covered by the first seed layer 81. In addition, a depth of the unit portion 163 of the accommodating hole 16 measured from the top surface 21 of the upper conductive structure 2 is defines as “D₁”. The first seed layer 81 extends to a first position “B” of the inner surface 161 of the unit portion 163. A depth of the first position “B” measured from the top surface 21 of the upper conductive structure 2 is defined as “D₂”. “D₂” is less than or equal to one half, one third or one fourth of “D₁”.

In some embodiments, the first seed layer 81 may include a basic layer 811 and an overlying layer 812. The basic layer 811 may be disposed on the first portion 161a of the inner surface 161 of the accommodating hole 16. The overlying layer 812 may be disposed on the basic layer 811. For example, the basic layer 811 may include titanium (Ti), tantalum (Ta) or titanium tungsten (TiW), and the overlying layer 812 may include copper (Cu).

The second seed layer 82 covers and contacts the first seed layer 81, and further extends to cover and contact the second portion 161b of the inner surface 161 of the accommodating hole 16. In some embodiments, the first seed layer 81 is formed by physical vapor deposition (PVD), and the second seed layer 82 is formed by electroless plating. A thickness of the second seed layer 82 is greater than a thickness of the first seed layer 81. For example, the thickness of the second seed layer 82 may be 0.4 μm, and the thickness of the first seed layer 81 may be 0.3 μm. Further, the second seed layer 82 include copper (Cu), and a grain size of the second seed layer 82 may be greater than the grain size of the overlying layer 812 of the first seed layer 81.

In some embodiments, a maximum width W₁ of the conductive through via 14 may be less than or equal to 20 μm, less than or equal to 15 μm, or less than or equal to 10 μm. Further, a width W₂ of the extending portion 146 may be less than or equal to 4 μm, less than or equal to 3 μm, or less than or equal to 1 μm.

The conductive through via 14 may include a plurality of unit portions 143 embedded in a respective one of the dielectric layers 20, 26, 27. Each of the unit portions 143 includes a first portion 141 and a second portion 142. The first portion 141 and the second portion 142 may correspond to the first portion 164 and the second portion 165 of the unit portion 163 of the accommodating hole 16, respectively. The first portion 141 may be embedded in an upper dielectric layer (e.g., the first dielectric layer 20), and the second portion 142 may be embedded in a lower dielectric layer (e.g., the second dielectric layer 26) under the upper dielectric layer (e.g., the first dielectric layer 20). A shape of the first portion 141 may be different from a shape of the second portion 142. The first portions 141 may extend through the dielectric layers 20, 26, 27, and may taper along a same direction (e.g., taper upwardly along the direction from the bottom surface 22 towards the top surface 21 of the upper conductive structure 2). Thus, the tapering direction of the unit portion 143 is same as a tapering direction of the inner conductive via 25.

A shape (and/or a size) of the first portion 141 of the unit portion 143 is substantially same as a shape (and/or a size) of the inner conductive via 25. In addition, the circuit layer 24 may include a plurality of pads 246 connecting to the bottom portion of inner conductive vias 25. The second portion 142 of the unit portion 143 may be connected to a bottom portion of the first portion 141 of the unit portion 143, and may be disposed on a surface of the dielectric layers 20, 26, 27. A shape (and/or a size) of the second portion 142 of the unit portion 143 is substantially same as a shape (and/or a size) of the pad 246 of the circuit layer 24.

The first portions 141 of the unit portions 143 may be arranged substantially in row, and may be aligned with one another. The first portions 141 and the central portions of the second portion 142 between two first portions 141 form the main portion 145. Further, a width W₁ of the second portion 142 of the unit portion 143 is greater than a width W₃ of the first portion 141 of the unit portions 143, so that the peripheral portion of the second portion 142 form the extending portion 146. The width W₂ of the extending portion 146 is equal to (W₁−W₃)/2. In some embodiments, the extending portion 146 (i.e., the peripheral portion) of the second portion 142 is disposed on a surface of the upper dielectric layer (i.e., the first dielectric layer 20).

The outer circuit layer 18 is disposed on the top surface 21 of the upper conductive structure 2 to physically connect or electrically connect the conductive through via(s) 14 and the exposed inner conductive via 25 of the upper conductive structure 2. In some embodiments, the outer circuit layer 18 may include a seed layer 8′ and a conductive material 144′ disposed on the seed layer 8′. The seed layer 8′ may include a first seed layer 81′ and a second seed layer 82′. The first seed layer 81′ may include a basic layer 811′ and an overlying layer 812′. The second seed layer 82′ covers and contacts the first seed layer 81′. The outer circuit layer 18 may be formed concurrently with the conductive through via 14. The seed layer 8′ is interposed between the conductive material 144′ and the top surface 21 of the upper conductive structure 2. The first seed layer 81′ (including the basic layer 811′ and the overlying layer 812′) of the outer circuit layer 18 and the first seed layer 81 (including the basic layer 811 and the overlying layer 812) of the conductive through via 14 may be the same layer. The second seed layer 82′ of the outer circuit layer 18 and the second seed layer 82 of the conductive through via 14 may be the same layer. The conductive material 144′ of the outer circuit layer 18 and the conductive material 144 of the conductive through via 14 may be the same layer.

As shown in the embodiment illustrated in FIG. 1 and FIG. 2, the wiring structure 1 is a combination of the upper conductive structure 2 and the lower conductive structure 3, in which the circuit layers 24 of the upper conductive structure 2 has fine pitch, high yield and low thickness; and the circuit layers 34, 38, 38′, 34a, 38a, 38a′ of the lower conductive structure 3 have low manufacturing cost. Thus, the wiring structure 1 has an advantageous compromise of yield and manufacturing cost, and the wiring structure 1 has a relatively low thickness. The manufacturing yield for one layer of the circuit layers 24 of the upper conductive structure 2 may be 99%, and the manufacturing yield for one layer of the circuit layers 34, 38, 38′, 34a 38a, 38a′ of the lower conductive structure 3 may be 90%. Thus, the yield of the wiring structure 1 may be improved. In addition, the warpage of the upper conductive structure 2 and the warpage of the lower conductive structure 3 are separated and will not influence each other. Thus, the warpage of the lower conductive structure 3 will not be accumulated onto the warpage of the upper conductive structure 2. Thus, the yield of the wiring structure 1 may be further improved.

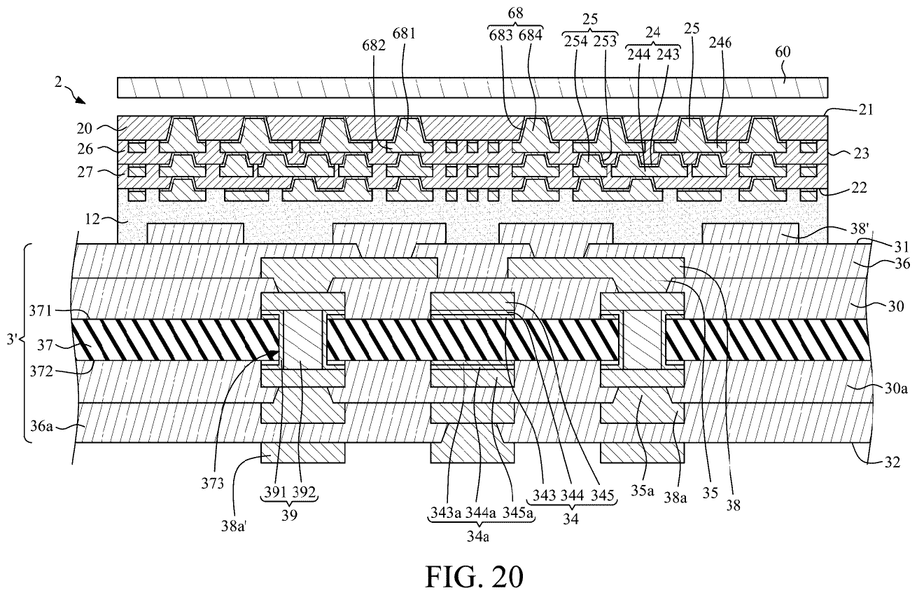

In addition, during the manufacturing process, the conductive through via 14 is formed or disposed in the accommodating hole 16 formed from a plurality of stacked portions 68 (including, for example, via portions 681 and pad portions 682) (FIG. 20). That is, the stacked portions 68 (including, for example, via portions 681 and pad portions 682) (FIG. 20) are removed completely to form the empty accommodating hole 16, then the conductive through via 14 is formed or disposed in the accommodating hole 16. Thus, a width and a profile of the accommodating hole 16 are defined and limited by the stacked portions 68 (FIG. 20). As a result, a width of the accommodating hole 16 may be relatively small, and the accommodating hole 16 may not have a barrel shape. Accordingly, the width of the conductive through via 14 may be relatively small, and the conductive through via 14 may not have a barrel shape.

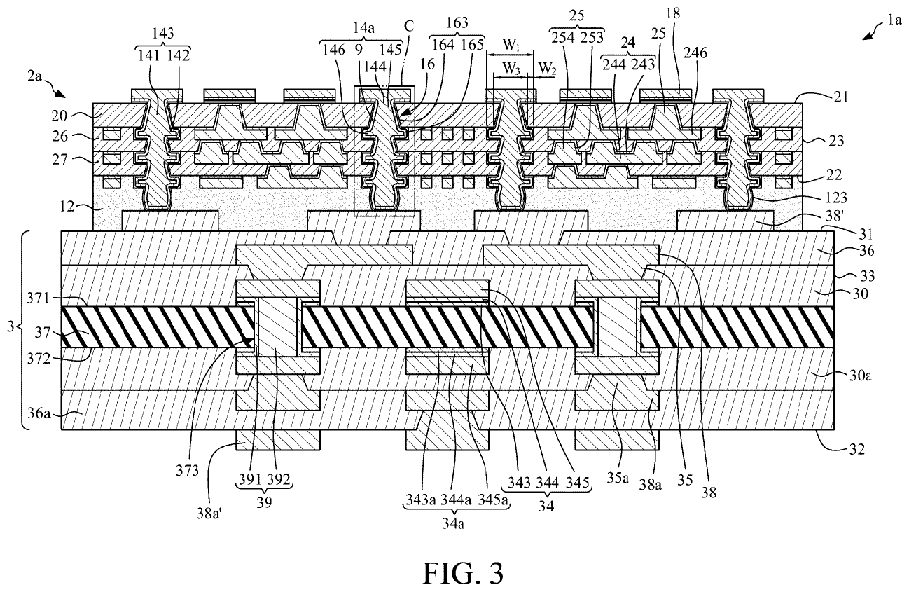

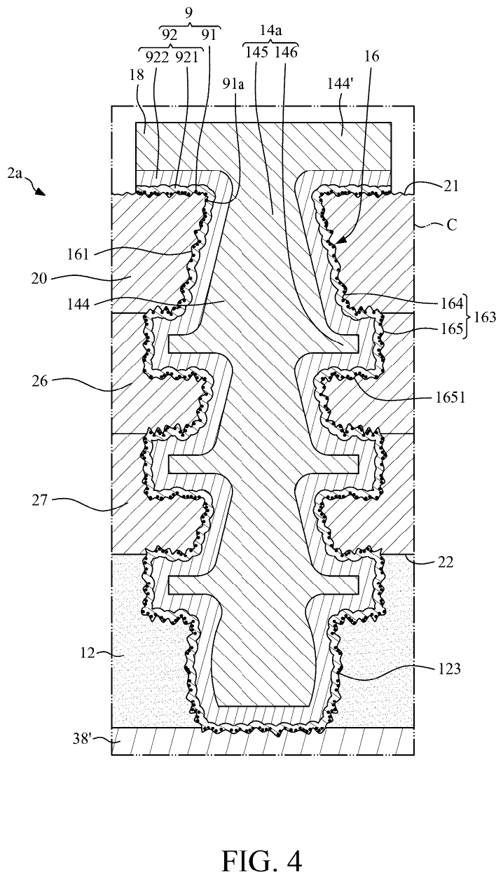

FIG. 3 illustrates a cross-sectional view of a wiring structure 1a according to some embodiments of the present disclosure. FIG. 4 illustrates a partially enlarged view of a region “C” in FIG. 3. The wiring structure 1a is similar to the wiring structure 1 shown in FIG. 1, except for a structure of the conductive through via 14a of the upper conductive structure 2a. The upper conductive structure 2a may be also referred to as “a conductive structure”.

As shown in FIG. 3 and FIG. 4, the seed layer 8 of FIG. 1 and FIG. 2 is replaced by the seed structure 9. Thus, the seed structure 9 of FIG. 3 and FIG. 4 is interposed between the main portion 145 and the dielectric layers 20, 26, 27, and between the extending portions 146 and the dielectric layers 20, 26. Thus, the main portion 145 and the extending portions 146 (e.g., the conductive material 144) may not contact the dielectric layers 20, 26, 27. The seed structure 9 may include an intermediate structure 91 and a seed layer 92. The intermediate structure 91 is bonded to the entire inner surface 161 of the accommodating hole 16 and the top surface 21 of the upper conductive structure 2a through chemical bond (e.g., covalent bond or ionic bond). The intermediate structure 91 may include a plurality of metal particles 91a, and the metal particles 91a may contact the inner surface 161 of the accommodating hole 16. The metal particles 91a in a unit region of the inner surface 161 of the accommodating hole 16 occupy more than 60% (or more than 80%) of the entire area of the unit region. In some embodiments, the metal particles 91a may be randomly distributed on the top surface 21 of the upper conductive structure 2a and the inner surface 161 of the accommodating hole 16. That is, the intermediate structure 91 may be discontinuous, and portions of the top surface 21 of the upper conductive structure 2a and portions of the inner surface 161 of the accommodating hole 16 may be exposed from the intermediate structure 91. Alternatively, the metal particles 91a may occupy more than 95% of the entire area of the inner surface 161 of the accommodating hole 16. That is, the intermediate structure 91 may be a continuous layer that covers the entire inner surface 161 of the accommodating hole 16 and the top surface 21 of the upper conductive structure 2a. In some embodiments, the intermediate structure 91 (or the metal particles 91a) may include palladium (Pd).

The seed layer 92 is bonded or coupled to the accommodating hole 16 through the intermediate structure 91. The seed layer 92 may cover and contact the intermediate structure 91. In addition, the seed layer 92 may cover and contact the exposed portions of the top surface 21 of the upper conductive structure 2a and the exposed portions of the inner surface 161 of the accommodating hole 16. The seed layer 92 may include a barrier layer 921 and a conductive layer 922. The barrier layer 921 may be disposed on the intermediate structure 91, and may cover and contact the intermediate structure 91. In addition, the barrier layer 921 may cover and contact the exposed portions of the top surface 21 of the upper conductive structure 2a and the exposed portions of the inner surface 161 of the accommodating hole 16. In some embodiments, the barrier layer 921 may include nickel (Ni). The conductive layer 922 may cover and contact the barrier layer 921. In some embodiments, the intermediate structure 91 may be formed by chemical bonding process, the barrier layer 921 may be formed by electroless plating, and the conductive layer 922 may be formed by electroless plating. In some embodiments, the conductive layer 922 may include copper (Cu). A thickness of the conductive layer 922 may be greater than a thickness of the barrier layer 921. For example, the thickness of the conductive layer 922 may be 1.0 to 2.0 μm, and the thickness of the barrier layer 921 may be 0.5 to 0.6 μm. As shown in FIG. 3 and FIG. 4, the conductive material (or a conductive channel) 144 may be disposed on the seed layer 92 of the seed structure 9 and may fill the accommodating hole 16 to form the conductive through via 14a.

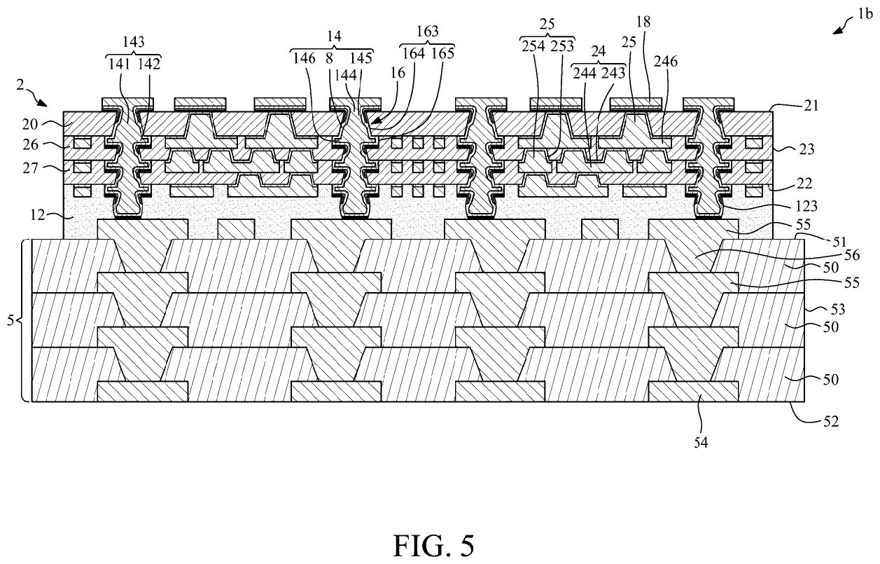

FIG. 5 illustrates a cross-sectional view of a wiring structure 1b according to some embodiments of the present disclosure. The wiring structure 1b is similar to the wiring structure 1 shown in FIG. 1, except for a structure of the lower conductive structure 5. As shown in FIG. 5, the lower conductive structure 5 may be a coreless substrate, and may include at least one dielectric layer (including, for example, three dielectric layers 50), at least one circuit layer (including, for example, three upper circuit layers 55 and one lower circuit layer 54 formed of a metal, a metal alloy, or other conductive material) in contact with the dielectric layer(s) 50 and at least one inner conductive via 56 (including, for example, a plurality of inner conductive vias 56). As shown in FIG. 5, the lower conductive structure 5 has a top surface 51, a bottom surface 52 opposite to the top surface 51, and a lateral surface 53 extending between the top surface 51 and the bottom surface 52. The lateral surface 23 of the upper conductive structure 2 may be displaced or recessed from the lateral surface 53 of the lower conductive structure 5. In some embodiments, the lateral surface 23 of the upper conductive structure 2 may be substantially coplanar with the lateral surface 53 of the lower conductive structure 5.

The lower circuit layer 54 is embedded in the bottommost dielectric layer 50, exposed from the bottom surface of the bottommost dielectric layer 50. The upper circuit layers 55 are disposed on the dielectric layers 50. Some of the inner conductive vias 56 are disposed between two adjacent upper circuit layers 55 for electrically connecting the two upper circuit layers 55. The inner conductive vias 56 and the upper circuit layer 55 may be formed integrally and concurrently. Some of the inner conductive vias 56 are disposed between the upper circuit layer 55 and the lower circuit layer 54 for electrically connecting the upper circuit layer 55 and the lower circuit layer 54. Each inner conductive via 56 tapers downwardly along a direction from the top surface 51 towards the bottom surface 52 of the lower conductive structure 5. Thus, a tapering direction of the inner conductive via 56 of the lower conductive structure 5 is different from the tapering direction of the inner conductive via 25 of the upper conductive structure 2.

A thickness of each of the dielectric layers 20, 26 of the upper conductive structure 2 is less than or equal to about 40%, less than or equal to about 35%, or less than or equal to about 30% of a thickness of each of the dielectric layers 50 of the lower conductive structure 5. In addition, a material of the dielectric layers 50 of the lower conductive structure 5 may be different from the material of the dielectric layers 20, 26 of the upper conductive structure 2. For example, the material of the dielectric layers 50 of the lower conductive structure 5 may be polypropylene (PP) or ajinomoto build-up film (ABF).

An L/S of the upper circuit layer 55 and the lower circuit layer 54 may be greater than or equal to about 10 μm/about 10 μm. Thus, the L/S of the upper circuit layer 55 and the lower circuit layer 54 may be greater than or equal to about five times the L/S of the circuit layers 24 of the upper conductive structure 2. In addition, in some embodiments, the topmost upper circuit layer 55 is disposed on and protrudes from the top surface of the topmost dielectric layer 50 (i.e., the top surface 51 of the lower conductive structure 5).

The bonding layer 12 is interposed or disposed between the upper conductive structure 2 and the lower conductive structure 5 to bond the upper conductive structure 2 and the lower conductive structure 5 together. In addition, the material of the bonding layer 12 may be different from the material of the dielectric layers 50 of the lower conductive structure 5. The conductive through via 14 may extend through the bonding layer 12, and is electrically connected to the topmost upper circuit layer 55 of the lower conductive structure 5.

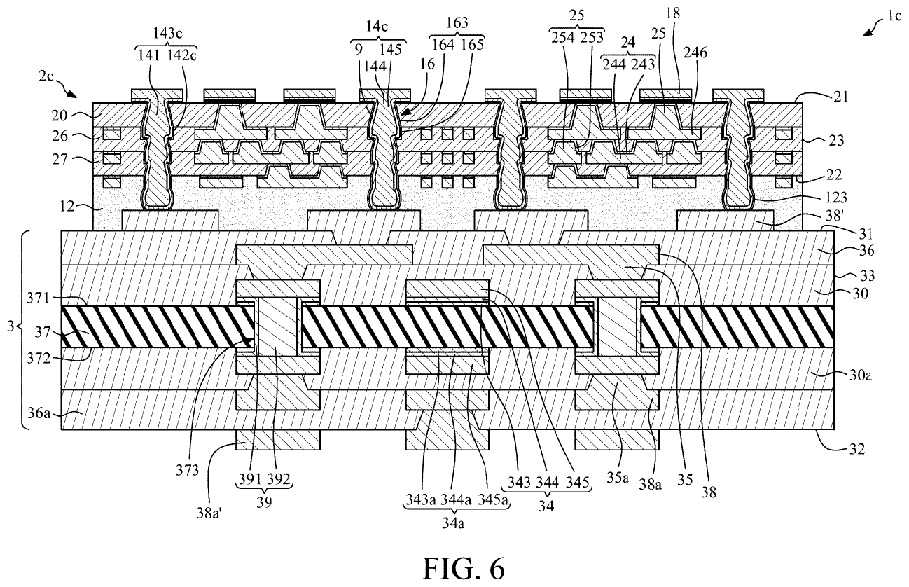

FIG. 6 illustrates a cross-sectional view of a wiring structure 1c according to some embodiments of the present disclosure. The wiring structure 1c is similar to the wiring structure 1 shown in FIG. 1, except for a structure of the conductive through via 14c. As shown in FIG. 6, the second portion 142c of the unit portion 143c of the conductive through via 14c does not include the extending portion 146 (i.e., the peripheral portion) of FIG. 1. Thus, the width W₂ of the extending portion 146 may be equal to zero.

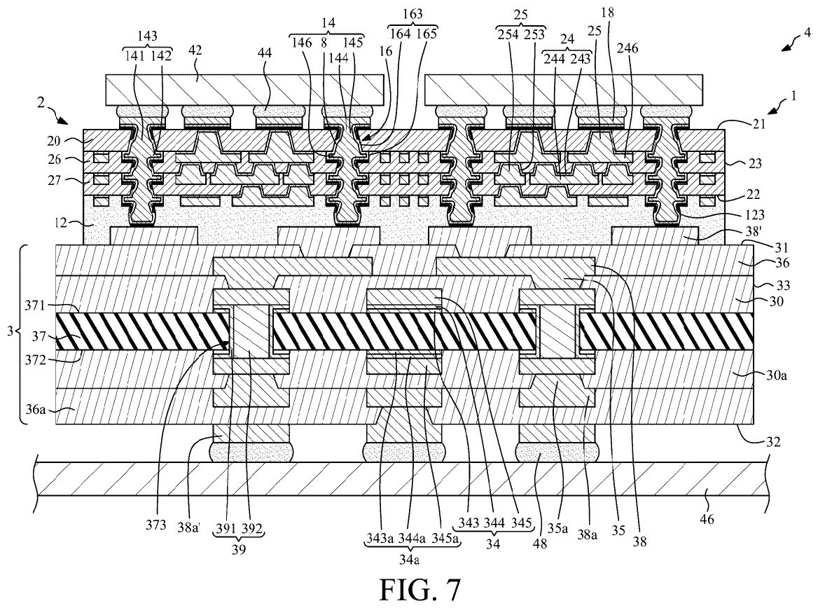

FIG. 7 illustrates a cross-sectional view of a bonding of a package structure 4 and a substrate 46 according to some embodiments. The package structure 4 includes a wiring structure 1, a semiconductor chip 42, a plurality of first connecting elements 44 and a plurality of second connecting elements 48. The wiring structure 1 of FIG. 7 is similar to the wiring structure 1 shown in FIG. 1. The semiconductor chip 42 is electrically connected and bonded to the outer circuit layer 18 through the first connecting elements 44 (e.g., solder bumps or other conductive bumps), so as to electrically connect the conductive through via(s) 14 and the inner conductive via 25 of the upper conductive structure 2. The second lower circuit layer 38a′ of the lower conductive structure 3 is electrically connected and bonded to the substrate 46 (e.g., a mother board such as a printed circuit board (PCB)) through the second connecting elements 48 (e.g., solder bumps or other conductive bumps).

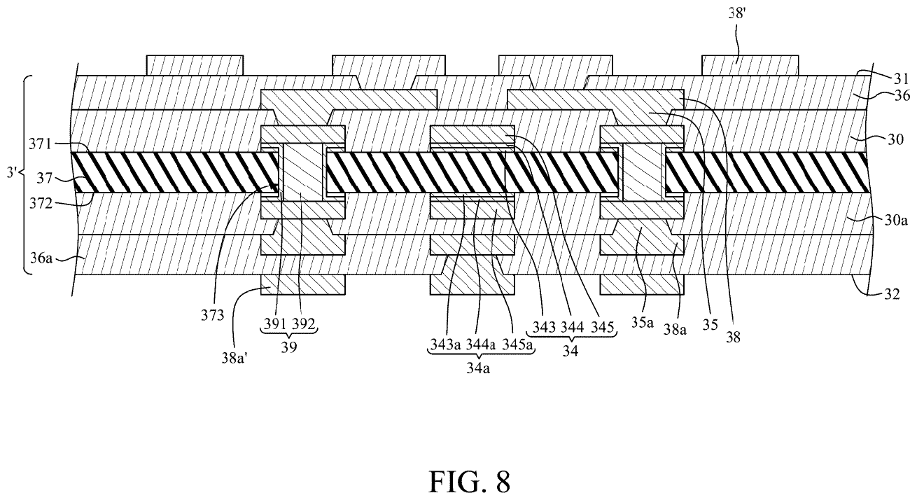

FIG. 8 through FIG. 25 illustrate a method for manufacturing a wiring structure according to some embodiments of the present disclosure. In some embodiments, the method is for manufacturing the wiring structure 1 shown in FIG. 1.

Referring to FIG. 8, a lower conductive structure 3′ is provided. The lower conductive structure 3′ is similar to the lower conductive structure 3 of FIG. 1, and includes the dielectric layers 30, 36, 30a, 36a, the circuit layers 34, 38, 38′, 34a, 38a, 38a′, the core portion 37, the upper interconnection vias 35 and the lower interconnection vias 35a. An electrical property (such as open circuit/short circuit) of the lower conductive structure 3′ may be tested.

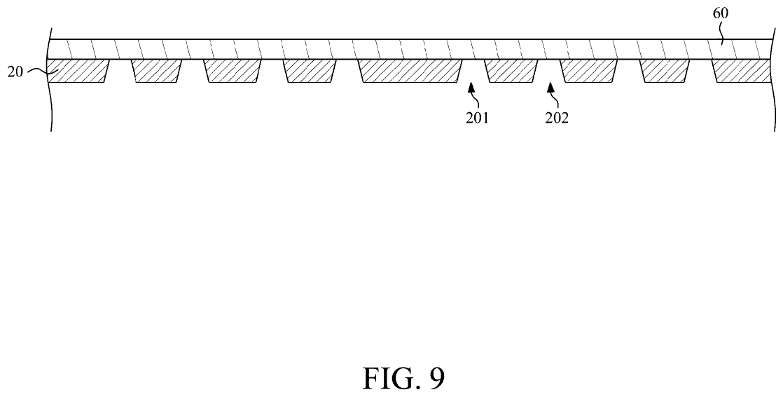

Referring to FIG. 9 through FIG. 18, an upper conductive structure 2 is provided. The upper conductive structure 2 is manufactured as follows. Referring to FIG. 9, a carrier 60 is provided. The carrier 60 may be a glass carrier, and may be in a wafer type, a panel type or a strip type. Then, a patterned first dielectric layer 20 is formed on the carrier 60. The patterned first dielectric layer 20 defines at least one first opening 201 and at least one second opening 202 extending through the first dielectric layer 20. A width of the first opening 201 may be equal to or different from a width of the second opening 202.

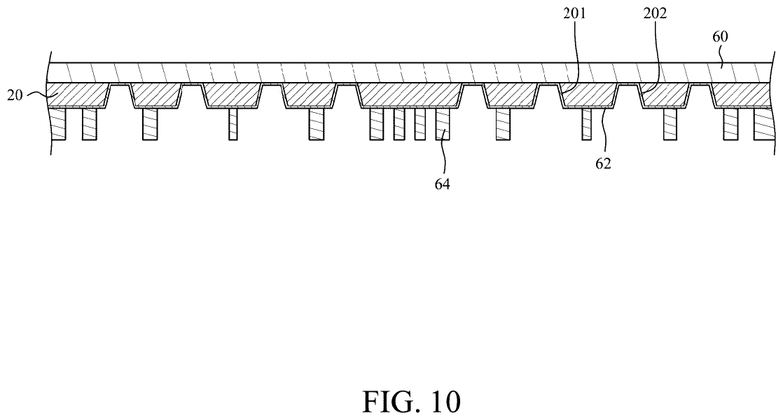

Referring to FIG. 10, a seed layer 62 is formed or disposed on the first dielectric layer 20, and in the first opening 201 and the second opening 202 by a physical vapor deposition (PVD) technique or other suitable techniques. Then, a first photoresist layer 64 is formed or disposed on the seed layer 62. Then, the first photoresist layer 64 is patterned to form a plurality of openings to expose portions of the seed layer 62 by an exposure and development technique or other suitable techniques.

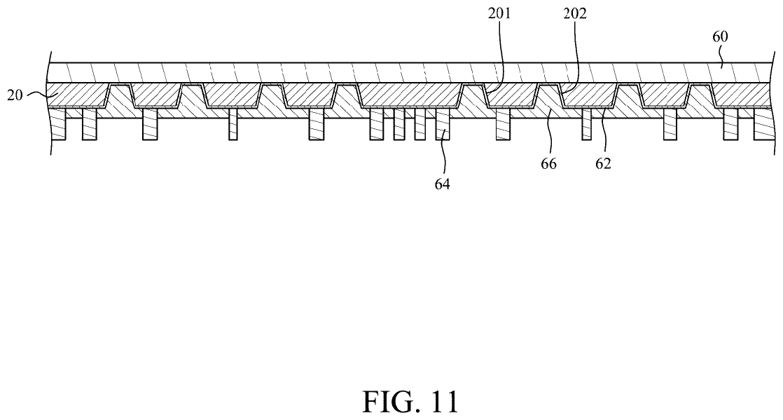

Referring to FIG. 11, a conductive material 66 (e.g., a metallic material) is disposed in the openings of the first photoresist layer 64 and on the seed layer 62 by a plating technique or other suitable techniques.

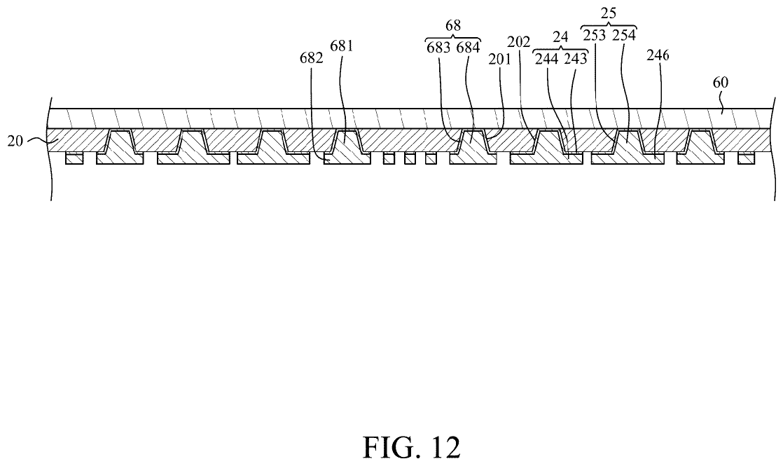

Referring to FIG. 12, the first photoresist layer 64 is removed by a stripping technique or other suitable techniques. Then, portions of the seed layer 62 that are not covered by the conductive material 66 are removed by an etching technique or other suitable techniques. Meanwhile, a circuit layer 24, at least one inner conductive via 25 and at least one stacking portion 68 are formed. The circuit layer 24 is disposed on a bottom surface of the first dielectric layer 20, and include a seed layer 243 formed from the seed layer 62 and a conductive material 244 disposed on the seed layer 243 and formed from the conductive material 66. The inner conductive via 25 is disposed in the second opening 202 of the first dielectric layer 20, and includes a seed layer 253 formed from the seed layer 62 and a conductive material 254 disposed on the seed layer 253 and formed from the conductive material 66. The stacking portion 68 is disposed in the first opening 201 of the first dielectric layer 20, and includes a seed layer 683 formed from the seed layer 62 and a conductive material 684 disposed on the seed layer 683 and formed from the conductive material 66. The stacking portion 68 may include a via portion 681 extending through the first dielectric layer 20 and a pad portion 682 on the via portion 681. A shape and a size of the via portion 681 of the stacking portion 68 may be same as or different from a shape and a size of the inner conductive via 25. A shape and a size of the pad portion 682 of the stacking portion 68 may be same as or different from a shape and a size of the pad 246 of the circuit layer 24.

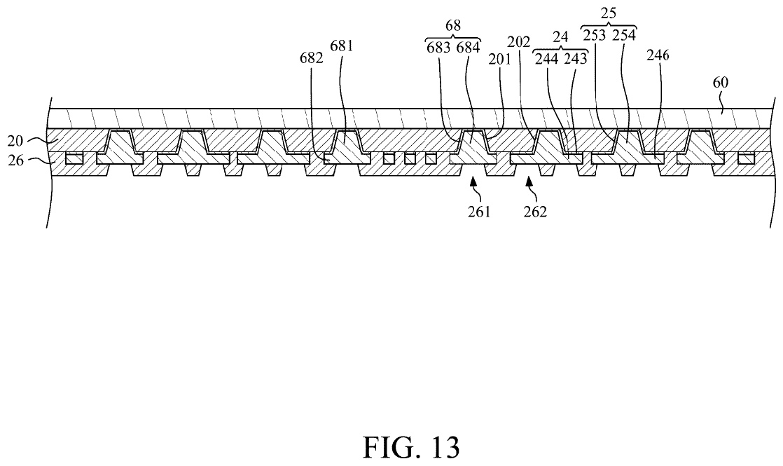

Referring to FIG. 13, a patterned second dielectric layer 26 is formed on the f dielectric layer 20 to cover the circuit layer 24 and the stacking portion(s) 68. The patterned second dielectric layer 26 defines at least one first opening 261 and at least one second opening 262 extending through the second dielectric layer 26. The first opening 261 is disposed on the stacking portion 68 so as to expose the pad portion 682 of the stacking portion 68. The second opening 262 is disposed on the circuit layer 24 so as to expose a portion of the circuit layer 24.

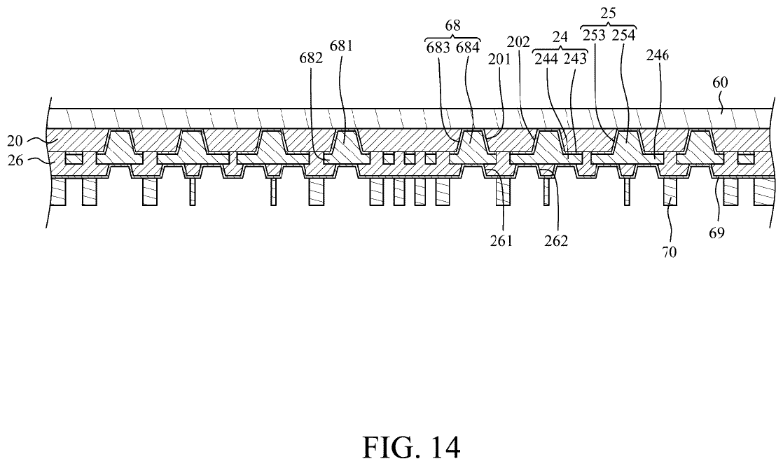

Referring to FIG. 14, a seed layer 69 is formed or disposed on the second dielectric layer 26, and in the first opening 261 and the second opening 262 by a physical vapor deposition (PVD) technique or other suitable techniques. Then, a second photoresist layer 70 is formed or disposed on the seed layer 69. Then, the second photoresist layer 70 is patterned to form a plurality of openings to expose portions of the seed layer 69 by an exposure and development technique or other suitable techniques.

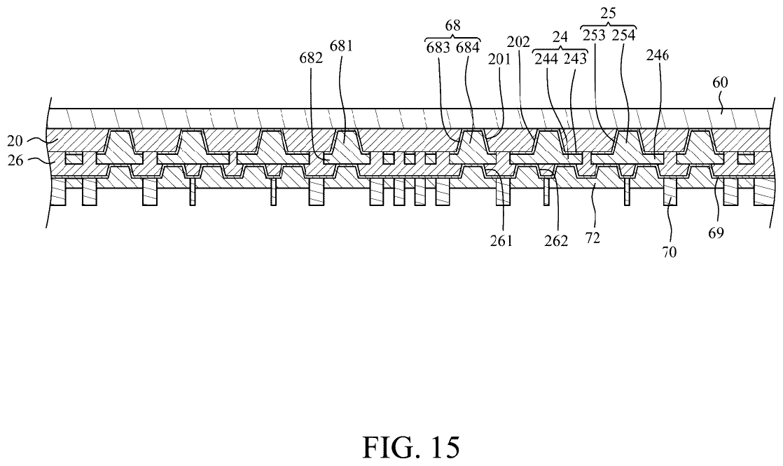

Referring to FIG. 15, a conductive material 72 (e.g., a metallic material) is disposed in the openings of the second photoresist layer 70 and on the seed layer 69 by a plating technique or other suitable techniques.

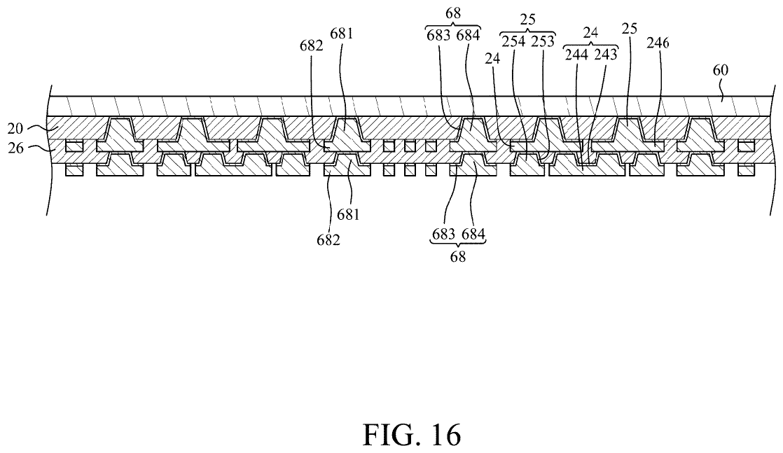

Referring to FIG. 16, the second photoresist layer 70 is removed by a stripping technique or other suitable techniques. Then, portions of the seed layer 69 that are not covered by the conductive material 72 are removed by an etching technique or other suitable techniques. Meanwhile, a circuit layer 24, at least one inner conductive via 25 and at least one stacking portion 68 are formed.

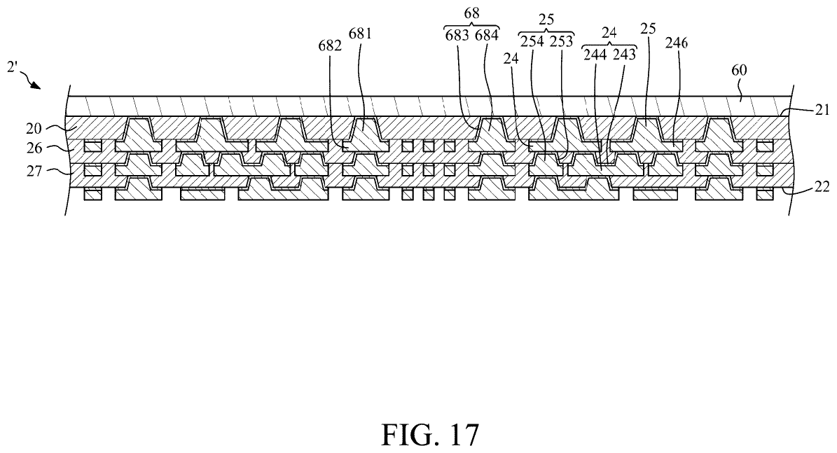

Referring to FIG. 17, the stages illustrated in FIG. 13 to FIG. 16 are repeated to form a patterned third dielectric layer 27, the circuit layers 24 on the dielectric layers 27, the inner conductive via 25 extending through the dielectric layer 27, and the stacking portions 68 embedded in the dielectric layer 27. In some embodiments, the stacking portions 68 in different dielectric layers may be arranged substantially in a row, and may be aligned with one another. In addition, the stacking portions 68 may connect one another or may be stacked with one another. Meanwhile, an upper conductive structure 2′ is formed on the carrier 60. The upper conductive structure 2′ may be tested.

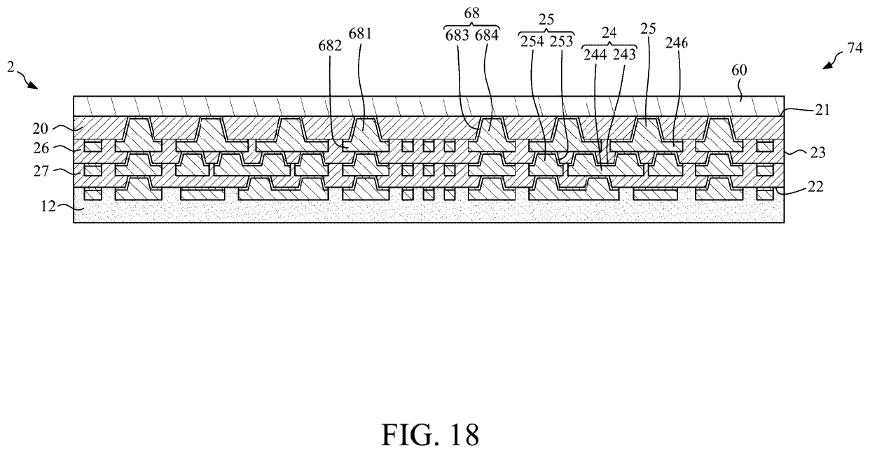

Referring to FIG. 18, the upper conductive structure 2′ and the carrier 60 are cut to form a plurality of unit structures 74. The unit structure 74 includes an upper conductive structure 2 and a portion of the carrier 60. The upper conductive structure 2 of FIG. 18 may be the upper conductive structure 2 of FIG. 1. Then, a bonding layer 12 is formed or applied on the bottom surface 22 of the upper conductive structure 2 (e.g., the bottom surface of the third dielectric layer 27).

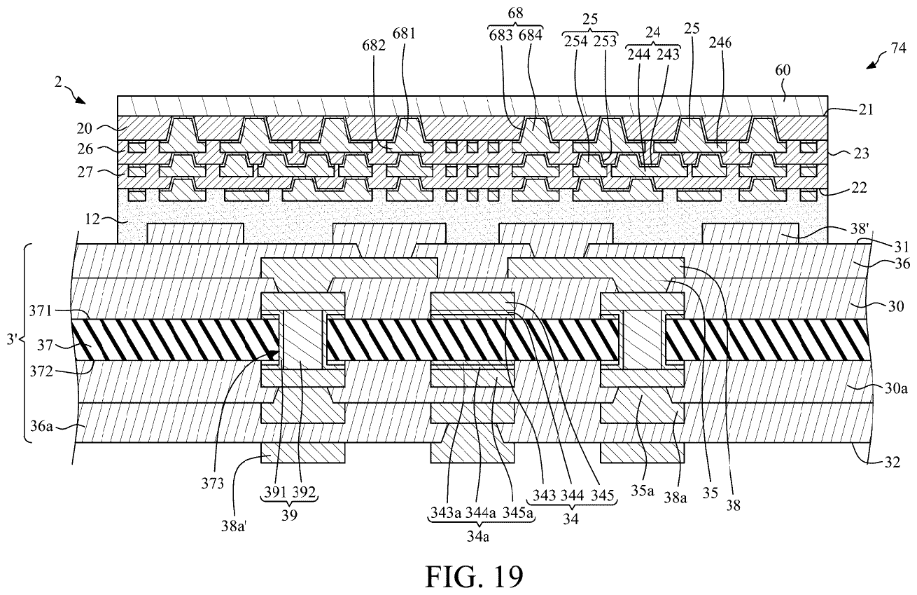

Referring to FIG. 19, the unit structure 74 is attached to the lower conductive structure 3′ of FIG. 8. The upper conductive structure 2 faces the lower conductive structure 3′. Thus, the upper conductive structure 2 and the carrier 60 are attached to the lower conductive structure 3′ through the bonding layer 12. Then, the bonding layer 12 may be cured.

Referring to FIG. 20, the carrier 60 is removed.

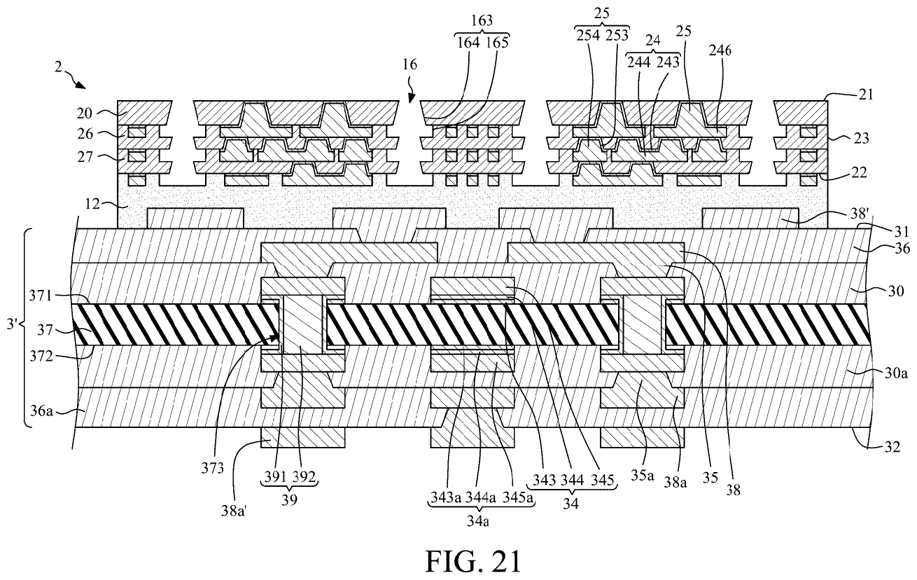

Referring to FIG. 21, the stacking portions 68 are removed to form at least one accommodating hole 16 through wet etching. The accommodating hole 16 may include a plurality of unit portions 163 corresponding to a respective one of the dielectric layers 20, 26, 27. Each of the unit portions 163 includes a first portion 164 and a second portion 165. The first portions 164 of the unit portions 163 taper upward. The second portion 165 is disposed on a bottom portion of the first portion 164 and extends horizontally.

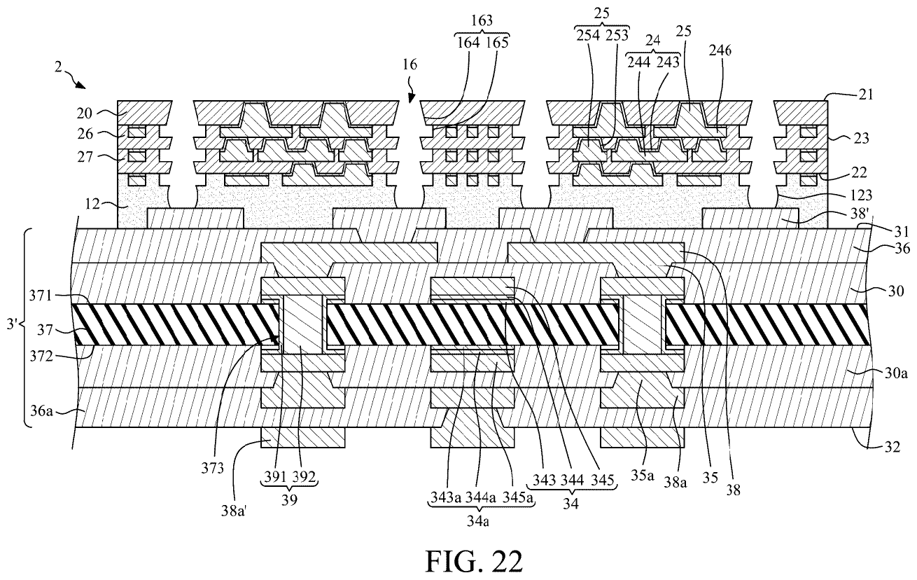

Referring to FIG. 22, a portion of the bonding layer 12 under the accommodating hole 16 are removed through laser drilling or plasma etching to form a through hole 123. Thus, the through hole 123 extends through the bonding layer 12, and terminates at or on the topmost circuit layer (e.g., the top surface of the second upper circuit layer 38′) of the lower conductive structure 3′. The through hole 123 may expose a portion of the topmost circuit layer (e.g., the second upper circuit layer 38′) of the lower conductive structure 3′. The through hole 123 may be aligned with and in communication with the accommodating hole 16 of the upper conductive structure 2. In some embodiments, the through hole 123 may be a portion of the accommodating hole 16.

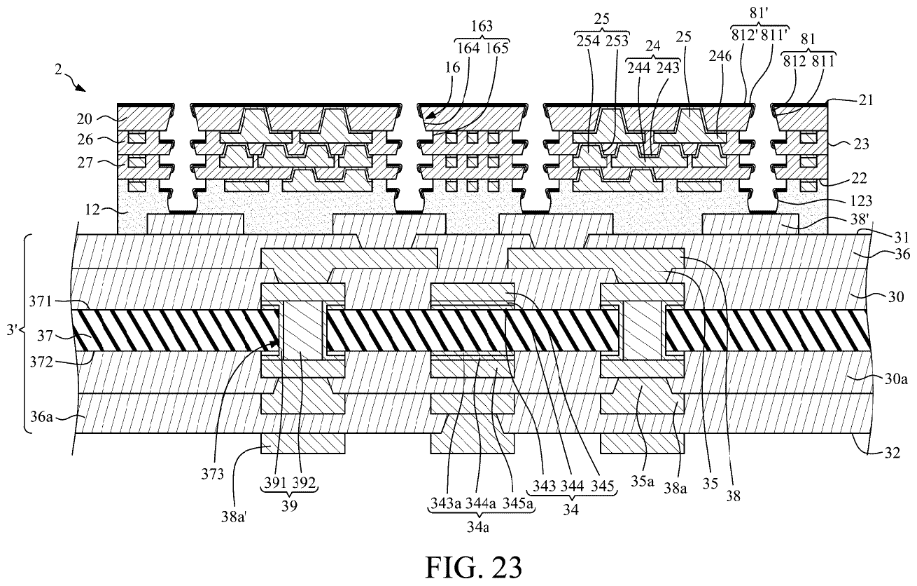

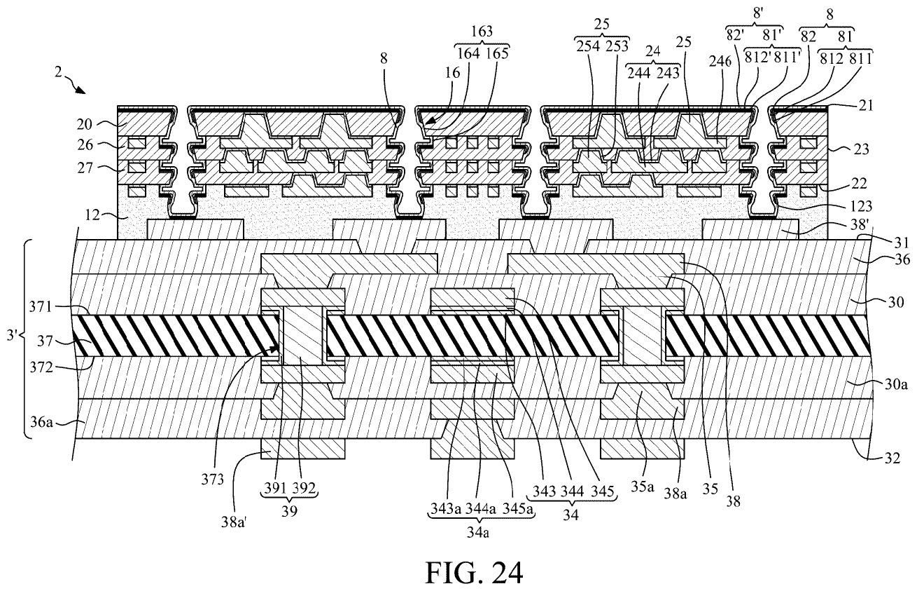

Referring to FIG. 23 and FIG. 24, a seed layer 8 is formed or disposed in the accommodating hole 16 and the through hole 123. The seed layer 8 may be formed as follows. Referring to FIG. 23, a basic layer 811 and an overlying layer 812 may be disposed on the first portion 161a (FIG. 2) of the inner surface 161 of the accommodating hole 16 by physical vapor deposition (PVD). The overlying layer 812 may be disposed on the basic layer 811 to form the first seed layer 81. For example, the basic layer 811 may a seed layer that includes titanium (Ti), tantalum (Ta) or titanium tungsten (TiW), and the overlying layer 812 may be a seed layer that includes copper (Cu). As shown in FIG. 23, since the first portions 164 of the unit portions 163 taper upward, the first seed layer 81 (including the basic layer 811 and the overlying layer 812) may be discontinuous in the accommodating hole 16. That is, the first seed layer 81 (including the basic layer 811 and the overlying layer 812) may not cover the entire inner surface of the accommodating hole 16.

Referring to FIG. 24, a second seed layer 82 is formed to cover and contact t first seed layer 81 and the second portion 161b (FIG. 2) of the inner surface 161 of the accommodating hole 16 by electroless plating, so as to form the seed layer 8. The second seed layer 82 may include copper (Cu), and a grain size of the second seed layer 82 may be greater than the grain size of the overlying layer 812 of the first seed layer 81. In some embodiments, a seed layer 8′ may be formed or disposed on the top surface 21 of the upper conductive structure 2. The seed layer 8′ (including the first seed layer 81′ and the second seed layer 82′) may be same as the seed layer 8 (including the first seed layer 81 and the second seed layer 82), and they may be formed concurrently and integrally.

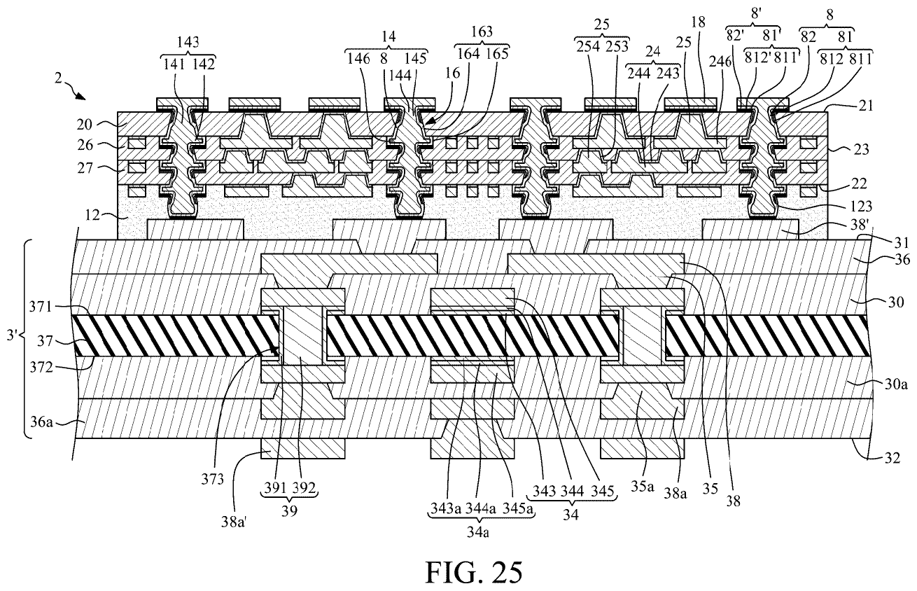

Referring to FIG. 25, a conductive material 144 is formed or disposed to fill t accommodating hole 16 and the through hole 123 through, for example, plating, so as to form a conductive through via 14 in the accommodating hole 16 and the through hole 123. The conductive through via 14 extends through the upper conductive structure 2 and the bonding layer 12, and contacts a portion of the topmost upper circuit layer (e.g., the second upper circuit layer 38′) of the lower conductive structure 3′. The conductive through via 14 includes plurality of unit portions 143. A shape and a size of each of the unit portions 143 may be same as a shape and a size of each of the stacking portions 68. In some embodiments, a conductive material 144′ may be formed or disposed on the seed layer 8′. The conductive material 144′ may be same as the conductive material 144, and they may be formed concurrently and integrally. Then, portions of the seed layer 8′ that are not covered by the conductive material 144′ are removed by an etching technique or other suitable techniques, so as to form an outer circuit layer 18.

Then, the lower conductive structure 3′ is singulated so as to obtain the wiring structure 1 of FIG. 1.

Since a width and a profile of the accommodating hole 16 are defined and limited by the stacking portions 68. As a result, a width of the accommodating hole 16 may be relatively small, and the accommodating hole 16 may not have a barrel shape. Accordingly, the width of the conductive through via 14 may be relatively small, and the conductive through via 14 may not have a barrel shape.

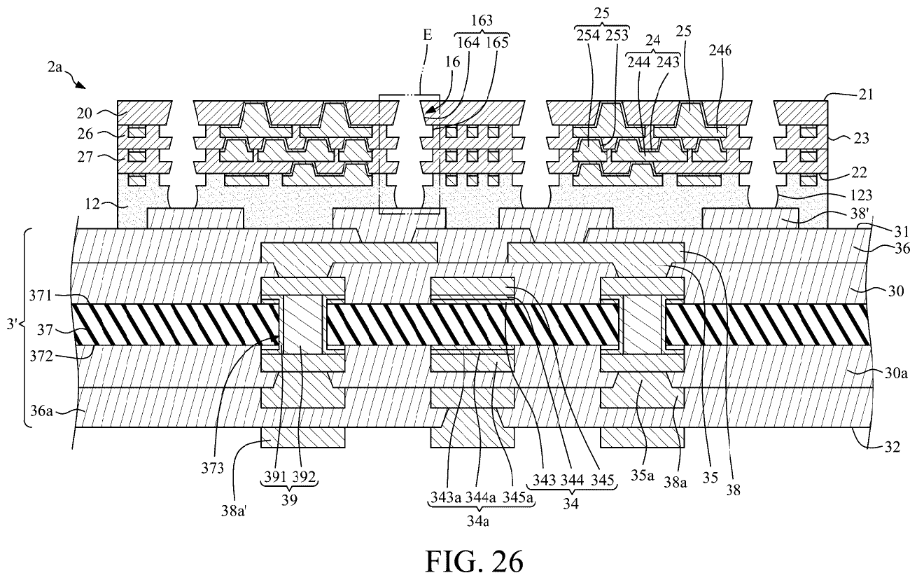

FIG. 26 through FIG. 33 illustrate a method for manufacturing a wiring structure according to some embodiments of the present disclosure. In some embodiments, the method is for manufacturing the wiring structure 1a shown in FIG. 3 and FIG. 4. The initial stages of the illustrated process are the same as, or similar to, the stages illustrated in FIG. 10 to FIG. 22. FIG. 26 depicts a stage subsequent to that depicted in FIG. 22.

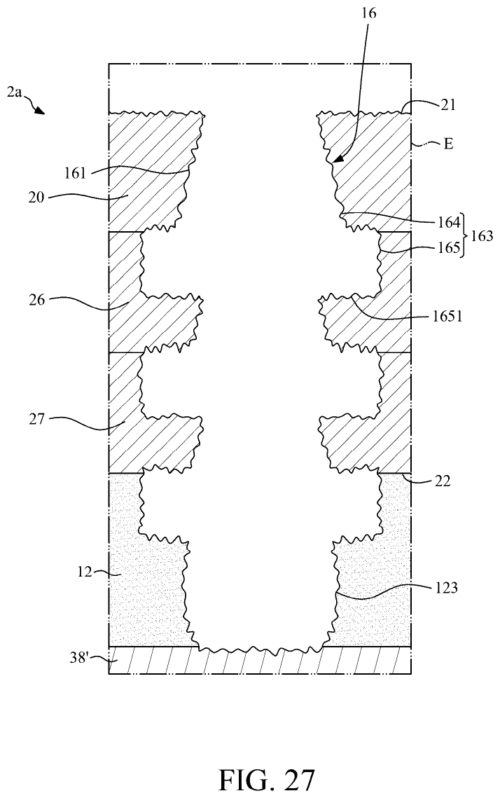

Referring to FIG. 26 and FIG. 27, wherein FIG. 27 illustrates a partially enlarged view of a region “E” in FIG. 26, the upper conductive structure 2a is immersed in a softening agent such as butyldiglycol so as to fluff the top surface 21 of the upper conductive structure 2a, the inner surface of the accommodating hole 16 and the inner surface of the through hole 123 of the bonding layer 12. Then, the upper conductive structure 2a is immersed in a strong oxidizing agent such as potassium permanganate (KMnO₄) so as to desmear the top surface 21 of the upper conductive structure 2a, the inner surface of the accommodating hole 16 and the inner surface of the through hole 123 of the bonding layer 12. Thus, the top surface 21 of the upper conductive structure 2a, the inner surface of the accommodating hole 16 and the inner surface of the through hole 123 of the bonding layer 12 are roughened, electrically polarized and are negatively charged. That is, there are negative charges (i.e. electrons) on the top surface 21 of the upper conductive structure 2a, the inner surface of the accommodating hole 16 and the inner surface of the through hole 123 of the bonding layer 12. The electrons are more than protons.

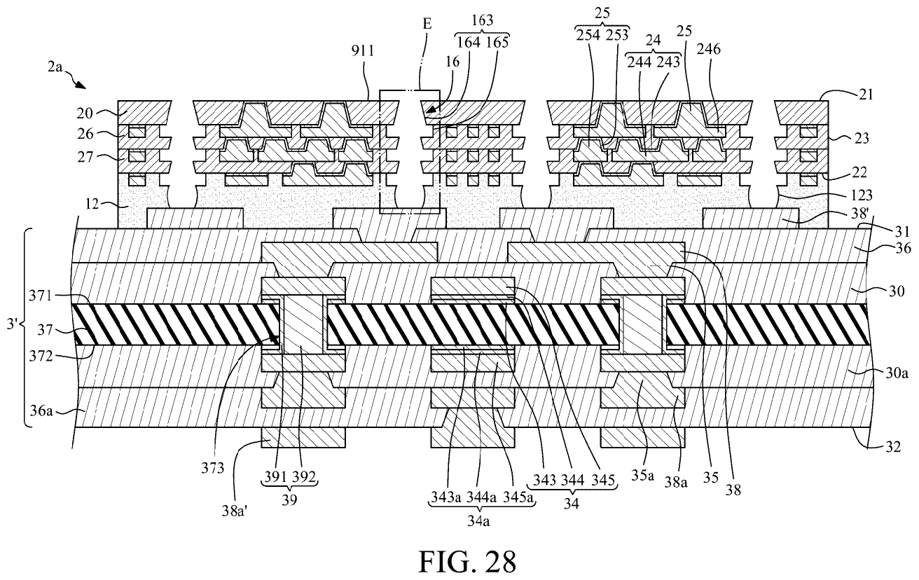

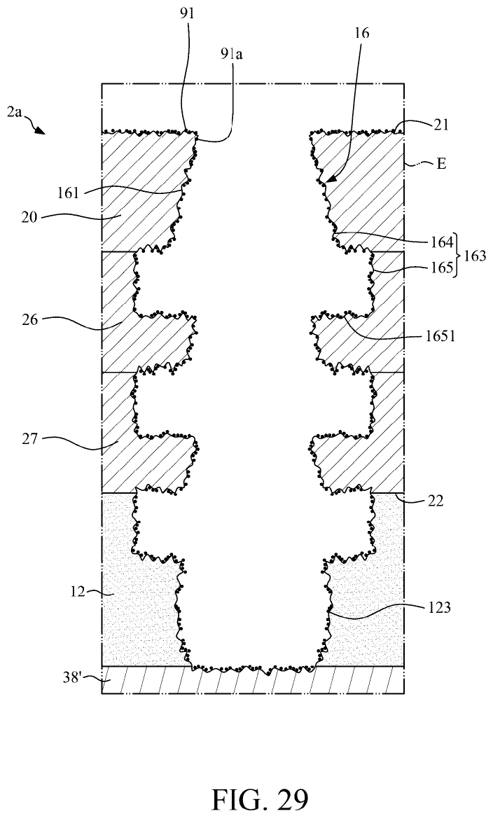

Referring to FIG. 28 and FIG. 29, wherein FIG. 29 illustrates a partially enlarged view of a region “E” in FIG. 28, positively charged particles (e.g., Pd²⁺ ions) are provided. It is noted that when an atom loses electron(s) it will lose some of its negative charge and so becomes positively charged. A positive ion is formed where an atom has more protons than electrons. In some embodiments, the upper conductive structure 2a is immersed in an activating agent including, for example, Dimethylamine borane (DMAB) and colloidal palladium so that positively charged particles (e.g., Pd²⁺ ions) are attached to the negatively charged top surface 21 of the upper conductive structure 2a, the negatively charged inner surface of the accommodating hole 16 and the negatively charged inner surface of the through hole 123 of the bonding layer 12 through chemical bonding such as covalent bonding or ionic bonding to form an intermediate structure 91. Thus, a plurality of metal particles 91a (e.g., palladium (Pd) cores) are randomly distributed on the top surface 21 of the upper conductive structure 2, the inner surface 161 of the accommodating hole 16 and the inner surface of the through hole 123 of the bonding layer 12 so as to form the intermediate structure 91.

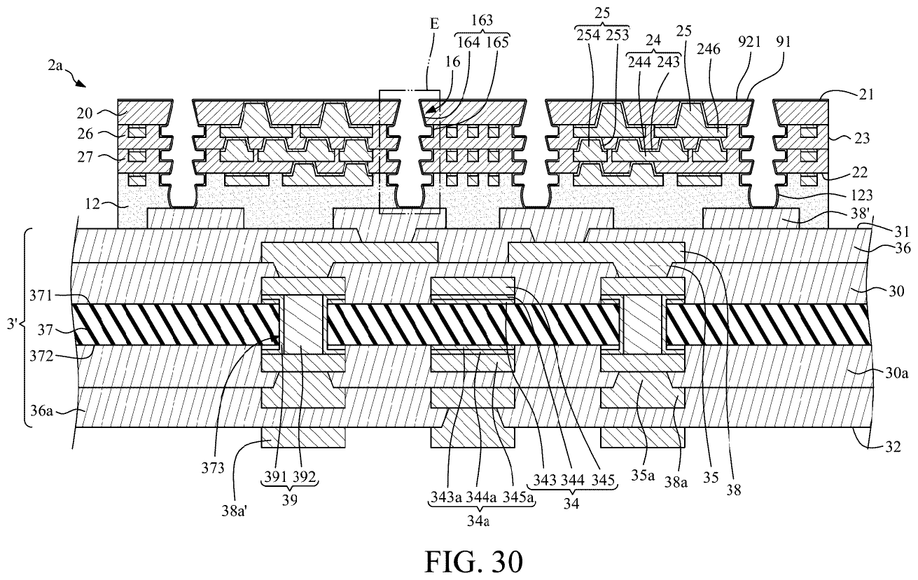

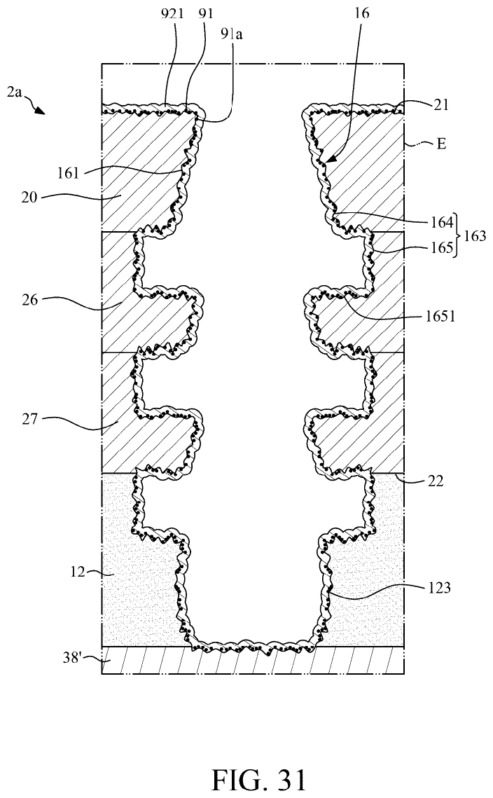

Referring to FIG. 30 to FIG. 33, a seed layer 92 is formed on the intermediate structure 91 by electroless plating as follows. Referring to FIG. 30 and FIG. 31, wherein FIG. 31 illustrates a partially enlarged view of a region “E” in FIG. 30, a barrier layer 921 is formed or disposed to cover and contact the intermediate structure 91 by electroless plating. In addition, the barrier layer 921 may cover and contact the exposed portions of the top surface 21 of the upper conductive structure 2a, the exposed portions of the inner surface 161 of the accommodating hole 16 and the exposed portions of the inner surface of the through hole 123 of the bonding layer 12. In some embodiments, the barrier layer 921 may include nickel (Ni).

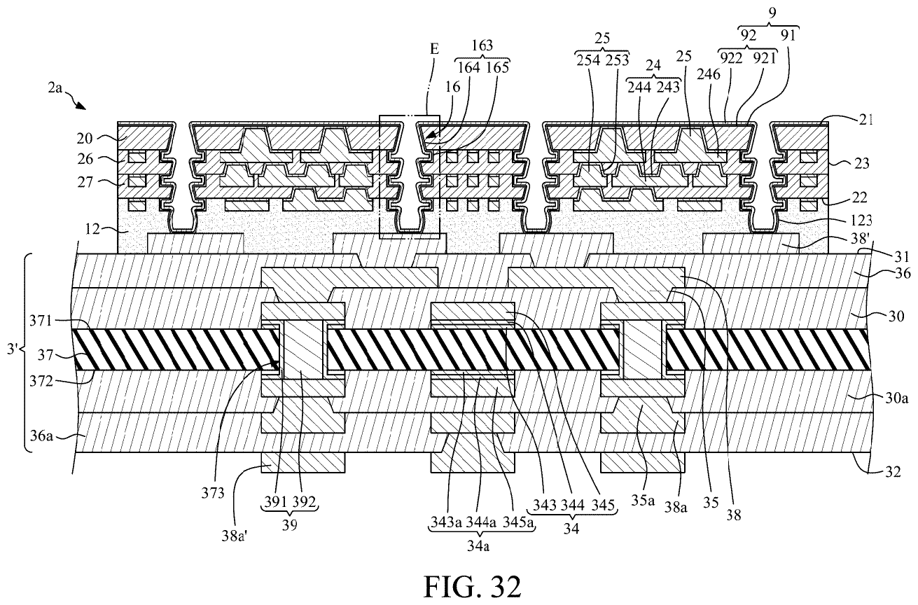

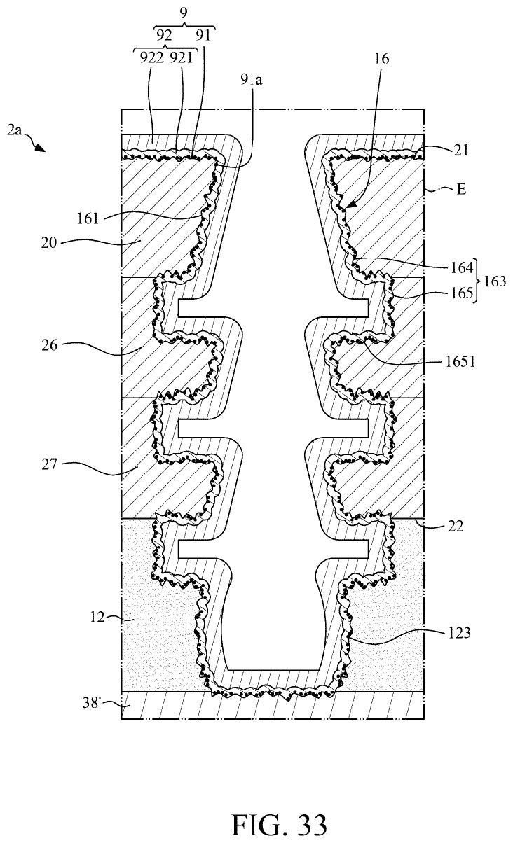

Referring to FIG. 32 and FIG. 33, wherein FIG. 33 illustrates a partially enlarged view of a region “E” in FIG. 32, a conductive layer 922 is formed or disposed to cover and contact the barrier layer 921 by electroless plating. In some embodiments, the conductive layer 922 may include copper (Cu). Meanwhile, the barrier layer 921 and the conductive layer 922 form a seed layer 92, and the intermediate structure 91 and the seed layer 92 form a seed structure 9. In a comparative embodiment, during the formation of the conductive layer 922 of the seed layer 92, if the barrier layer 921 is omitted, ion exchange reaction may occur between the conductive layer 922 (i.e., copper (Cu)) and the intermediate structure 91 (i.e., palladium (Pd) cores). Thus, the metal particles 91a (e.g., palladium (Pd) cores) may leave the top surface 21 of the upper conductive structure 2a, the inner surface 161 of the accommodating hole 16 and the inner surface of the through hole 123 of the bonding layer 12, and the conductive layer 922 may not be disposed on the top surface 21 of the upper conductive structure 2a, the inner surface 161 of the accommodating hole 16 and the inner surface of the through hole 123 of the bonding layer 12 securely. To address such concerns, the barrier layer 921 (e.g., nickel (Ni)) is interposed between the intermediate structure 91 and the conductive layer 922 to prevent such ion exchange reaction between the conductive layer 922 (i.e., copper (Cu)) and the intermediate structure 91 (i.e., palladium (Pd) cores). That is, the barrier layer 921 (e.g., nickel (Ni)) is used as an isolation layer.

Then, the following stages of the illustrated process are the same as, or similar to, the stage illustrated in FIG. 25, so as to obtain the wiring structure 1a shown in FIG. 3 and FIG. 4.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, a characteristic or quantity can be deemed to be “substantially” consistent if a maximum numerical value of the characteristic or quantity is within a range of variation of less than or equal to +10% of a minimum numerical value of the characteristic or quantity, such as less than or equal to +5%, less than or equal to +4%, less than or equal to +3%, less than or equal to +2%, less than or equal to +1%, less than or equal to +0.5%, less than or equal to +0.1%, or less than or equal to +0.05%.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A method for manufacturing a wiring structure, comprising:
(a) providing a lower conductive structure including a plurality of dielectric layers, a plurality of circuit layers in contact with the plurality of dielectric layers and a plurality of inner conductive vias electrically connecting two adjacent circuit layers;
(b) providing an upper conductive structure including a plurality of dielectric layers, a plurality of circuit layers in contact with the plurality of dielectric layers, a plurality of inner conductive vias electrically connecting two adjacent circuit layers and a plurality of stacking portions connecting one another, wherein a line width/line space (L/S) of the plurality of circuit layers of the lower conductive structure is greater than an L/S of the plurality of circuit layers of the upper conductive structure;
(c) attaching the upper conductive structure to the lower conductive structure 3′;
(d) removing the stacking portions to form an accommodating hole;
(e) forming a seed layer on an inner surface of the accommodating hole; and
(f) forming a conductive material on the seed layer to form a conductive through via in the accommodating hole, wherein the conductive through via extends through the upper conductive structure and contacts the circuit layer of the lower conductive structure.

2. The method of claim 1, wherein in (b), one of the plurality of stacking portions includes a via portion extending through the dielectric layer of the upper conductive structure and a pad portion on the via portion, wherein a shape and a size of the via portion of the one of the plurality of stacking portions is the same as a shape and a size of one of the plurality of inner conductive vias of the upper conductive structure, wherein the one of the plurality of stacking portions and the one of the plurality of inner conductive vias of the upper conductive structure are formed concurrently.

3. The method of claim 1, wherein in (c), the upper conductive structure is attached to the lower conductive structure through a bonding layer; wherein in (d), the plurality of stacking portions and a portion of the bonding layer are removed to form the accommodating hole.

4. The method of claim 3, wherein in (c), the plurality of stacking portions are removed through wet etching, and the portion of the bonding layer is removed through laser drilling or plasma etching.

5. The method of claim 1, wherein after (c), the plurality of stacking portions and the plurality of inner conductive vias taper away from the lower conductive structure.

6. The method of claim 5, wherein a tapering direction of the plurality of inner conductive vias of the lower conductive structure is different from a tapering direction of the plurality of inner conductive vias of the upper conductive structure.

7. The method of claim 5, wherein after (d), the accommodating hole includes a plurality of unit portions corresponding to the plurality of dielectric layers of the upper conductive structure 2, wherein one of the plurality of unit portions includes a first portion and a second portion, the first portion of the one of the plurality of unit portions tapers away from the lower conductive structure, wherein the second portion of the one of the plurality of unit portions is disposed on a bottom portion of the first portion and extends horizontally.

8. The method of claim 7, wherein (e) further comprises:
(e1) forming a basic layer on a first portion of the inner surface of the accommodating hole; and
(e2) forming an overlying layer on the basic layer to form a first seed layer, wherein the first seed layer is discontinuous in the accommodating hole, and a second portion of the inner surface of the accommodating hole is exposed.

9. The method of claim 8, wherein the basic layer is formed by physical vapor deposition (PVD), and includes titanium (Ti), tantalum (Ta) or titanium tungsten (TiW), wherein the overlying layer is formed by PVD, and includes copper (Cu).

10. The method of claim 8, wherein a depth of the one of the plurality of unit portions of the accommodating hole measured from a top surface of the upper conductive structure is defines as D₁, a depth of the first portion of the inner surface of the accommodating hole measured from the top surface of the upper conductive structure is defined as D₂, wherein D₂ is less than or equal to one half of D₁.

11. The method of claim 8, wherein (e) further includes:
(e3) forming a second seed layer to cover and contact the first seed layer and the second portion of the inner surface of the accommodating hole.

12. The method of claim 11, wherein the second seed layer is formed by electroless plating and includes copper (Cu).

13. The method of claim 11, wherein a grain size of the second seed layer is greater than a grain size of the overlying layer of the first seed layer.

14. The method of claim 1, wherein after (d), the method further includes:
(d1) fluffing the inner surface of the accommodating hole; and
(d2) desmearing the inner surface of the accommodating hole, wherein the inner surface of the accommodating hole is roughened, electrically polarized and negatively charged.

15. The method of claim 14, wherein (d1) further includes immersing the upper conductive structure in a softening agent including butyldiglycol so as to fluff the inner surface of the accommodating hole, wherein (d2) further includes immersing the upper conductive structure in a strong oxidizing agent including potassium permanganate (KMnO₄) as to desmearing the accommodating hole.

16. The method of claim 14, wherein (e) further includes:
(e1) attaching a plurality of positively charged particles to the inner surface of the accommodating hole through chemical bonding so as to form an intermediate structure; and
(e2) electroless plating the seed layer to cover and contact the intermediate structure and the inner surface of the accommodating hole.

17. The method of claim 16, wherein (e1) further includes immersing the upper conductive structure in an activating agent including Dimethylamine borane (DMAB) and colloidal palladium.

18. The method of claim 17, wherein the plurality of positively charged particles include plurality of palladium (Pd) cores randomly distributed on the inner surface of the accommodating hole.

19. The method of claim 16, wherein (e2) further includes:
(e21) forming a barrier layer to cover and contact the intermediate structure and the inner surface of the accommodating hole; and
(e22) forming a conductive layer to cover and contact the barrier layer.

20. The method of claim 19, wherein the barrier layer includes nickel (Ni), and the conductive layer includes copper (Cu).
